(19) United States
(12) Patent Application Publication
(10) Pub. No.: US 2026/0170220 A1
(43) Pub. Date: Jun. 18, 2026

(54) MEMORY WITH BUNDLE-WIDE ACCESS LINES, METHOD OF READING FROM THE SAME AND METHOD OF MANUFACTURING SAME

(71) Applicants: TAIWAN SEMICONDUCTOR MANUFACTURING COMPANY, LTD., Hsinchu (TW); TSMC CHINA COMPANY, LIMITED, Shanghai (CN)

(72) Inventors: Yang GENG, Hsinchu (TW); Kuang Ting CHEN, Hsinchu (TW); YanJing TANG, Hsinchu (TW); Ching-Wei WU, Hsinchu (TW)

(21) Appl. No.: 19/009,372

(22) Filed: Jan. 3, 2025

(30) Foreign Application Priority Data
Dec. 16, 2024 (CN) 202411856743.9

(51) Int. Cl. G06F 30/394; G06F 30/396

(52) U.S. Cl. CPC G06F 30/394; G06F 30/396

(57) ABSTRACT

A memory includes first, second, third and fourth banks stacked on each other relative to a first direction and correspondingly including memory cells. Each of first to fourth banks includes first and second partitions separated from each other by a local access manager relative to the first direction. The (A) the first and second banks and (B) the third and fourth banks are organized as corresponding first and second bundles. The memory further includes a global access manager separating the first and second bundles relative to the first direction. The global access manager being separately coupled to the first and second bundles by corresponding first and second bundle-wide write lines or corresponding first and second bundle-wide read lines. The global access manager is configured to selectively access the first and second bundles on a mutually exclusive basis.

### PRIORITY

This application claims the priority of China Application No. 202411856743.9, filed Dec. 16, 2024, which is incorporated herein by reference in its entirety.

### BACKGROUND

The semiconductor integrated circuit (IC) industry produces a wide variety of analog and digital devices to address issues in a number of different areas. Developments in semiconductor process technology nodes have progressively reduced component sizes and tightened spacing resulting in progressively increased transistor density. ICs have become smaller.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a block diagram, in accordance with some embodiments.

FIGS. 2A-2E are corresponding schematic diagrams, in accordance with some embodiments.

FIGS. 3A-3B and 4 are corresponding timing diagrams, in accordance with some embodiments.

FIGS. 5, 6A-6D and 7 are flowcharts of corresponding methods, in accordance with some embodiments.

FIG. 8 is a block diagram of an electronic design automation (EDA) system in accordance with some embodiments.

FIG. 9 is a block diagram of an integrated circuit (IC) manufacturing system, and an IC manufacturing flow associated therewith, in accordance with some embodiments.

### DETAILED DESCRIPTION

The following disclosure discloses many different embodiments, or examples, for implementing different features of the subject matter. Examples of components, materials, values, steps, operations, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows include embodiments in which the first and second features are formed in direct contact, and further include embodiments in which additional features are formed between the first and second features, such that the first and second features are in indirect contact. In addition, the present disclosure repeats reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, are used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus is otherwise oriented (rotated 90 degrees or at other orientations) and the spatially relative descriptors used herein are likewise interpreted accordingly. In some embodiments, the term standard cell structure refers to a standardized building block included in a library of various standard cell structures. In some embodiments, various standard cell structures are selected from a library thereof and are used as components in a layout diagram representing a circuit.

In some embodiments, a memory includes first, second, third and fourth banks stacked on each other relative to a first direction and correspondingly including memory cells. Each of first to fourth banks includes first and second partitions and a local access manager. The (A) the first and second banks and (B) the third and fourth banks are organized as corresponding first and second bundles. The memory further includes a global access manager separating the first and second bundles relative to the first direction. The global access manager being separately coupled to the first and second bundles by corresponding first and second bundle-wide write lines or corresponding first and second bundle-wide read lines. The global access manager is configured to selectively access the first and second bundles on a mutually exclusive basis.

Consider a memory according to another approach that is a counterpart to a memory according to one or more present embodiments (present memories), where the counterpart memory includes banks that are counterparts to the present banks, global input/output (I/O) circuits that are counterparts to global I/O (GIO) circuits included in the present global access manager, a global controller (GCNT) that is a counterparts to a present GCNT included in the present GCNT, and local I/O circuits (LIOs) that are counterparts to present LIOs included in local access managers. Each counterpart GIO circuit is coupled to the counterpart GIO by memory-wide signal lines. Because each of the memory-wide signal lines according to the other approach are coupled to each of the counterpart LIOs, the memory-wide signal lines according to the other approach extend into all the counterpart banks such that the memory-wide signal lines according to the other approach are long.

As part of developing at least some of the present memories, one or more of the present inventors recognized at the least the following: because the memory-wide signal lines according to the other approach are long, consequently the memory-wide signal lines according to the other approach experience significant resistive-capacitive (RC) loading which reduces signal propagation speeds, degrades signal quality and increases power consumption, or the like; about 20% of the power consumed during a read phase in the operation of the counterpart memory, for example, is consumed by the global bit line of counterpart memory; and there was an opportunity to reduce signal line lengths as compared to the memory according to another approach. Accordingly, at least some of the present memories reduce the lengths of access lines by using bundle-wide access lines which improves signal propagation speeds, improves signal quality and reduces power consumption, or the like, as compared to the use of memory-wide signal lines in the memory according to another approach. One or more of the present memories reduces power consumption by about 13% as compared to the memory according to another approach. Regarding one or more of the present memories, the use of bundle-wide access lines by corresponding one of more of the present GIOs and reduces power consumption associated with the same by about 19% as compared to the power consumption associated with the use of the memory-wide signal lines by the counterpart GIO according to the other approach.

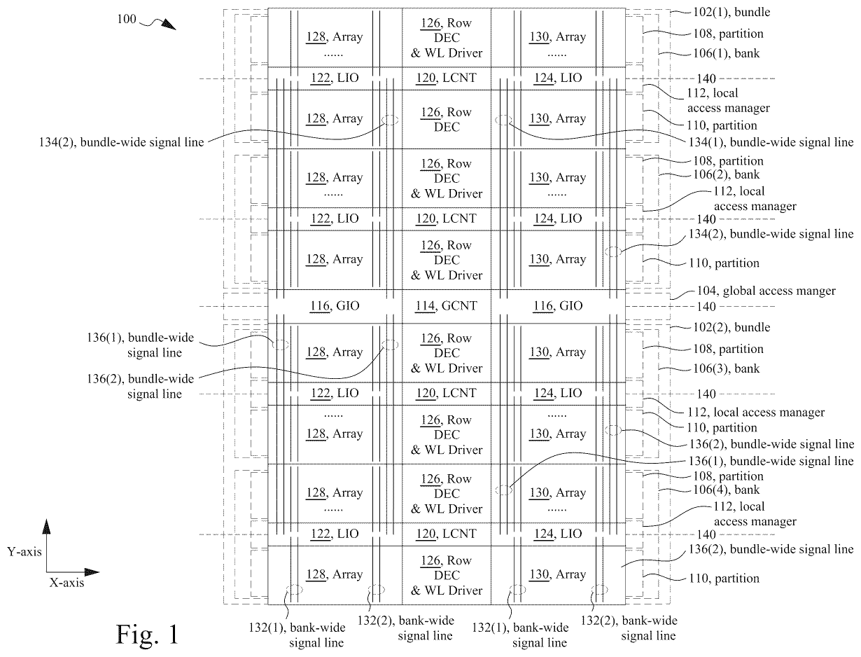

FIG. 1 is a block diagram of a memory 100, in accordance with some embodiments.

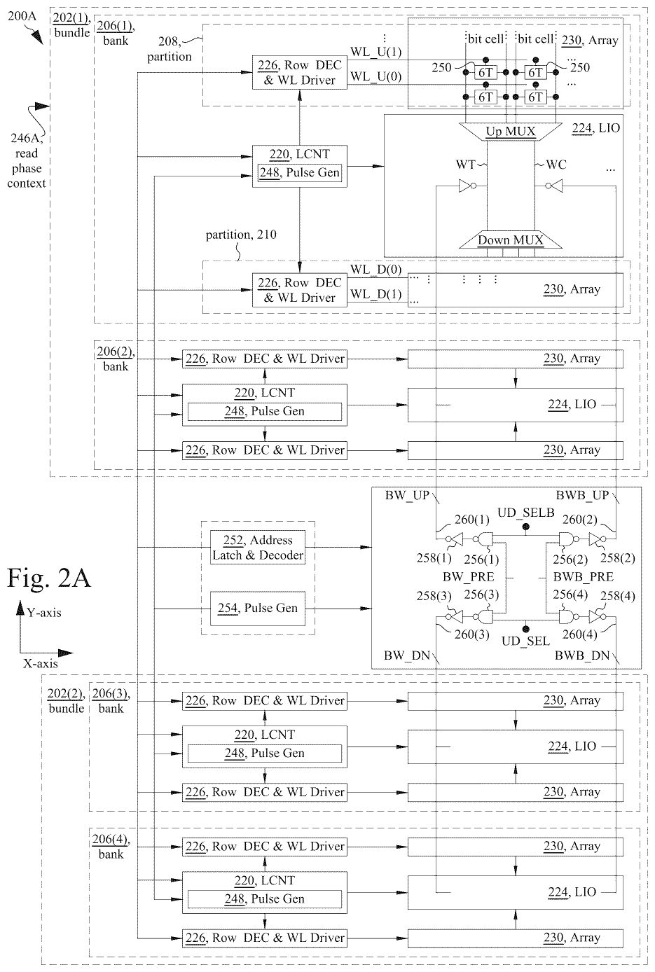

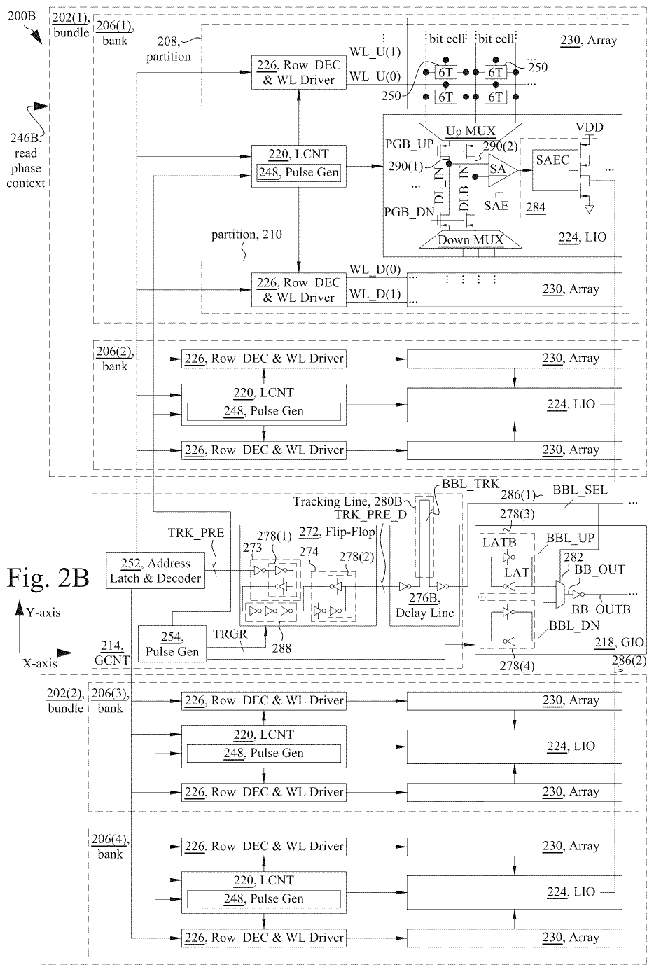

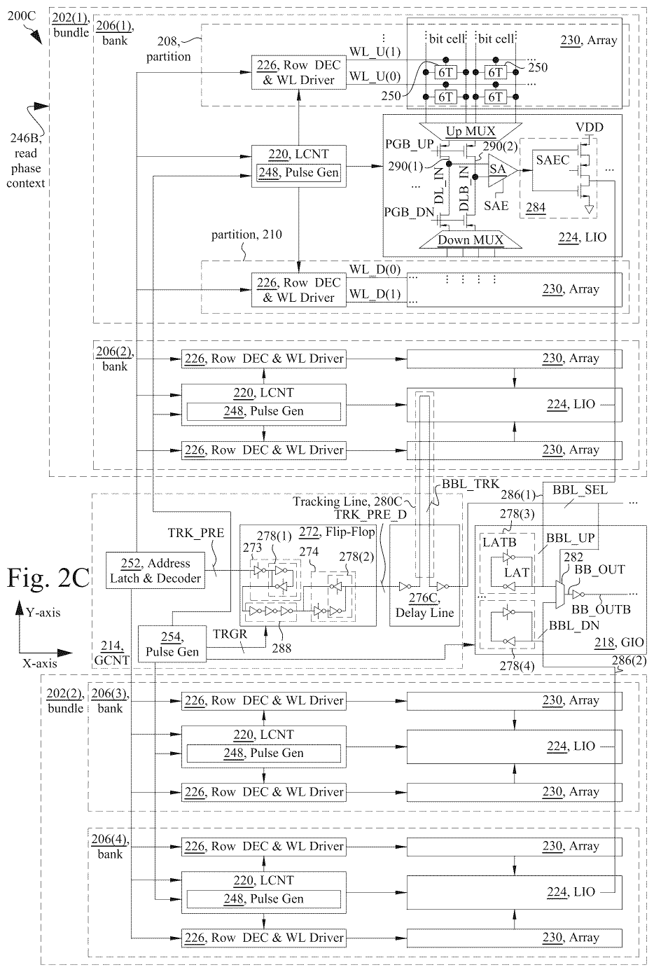

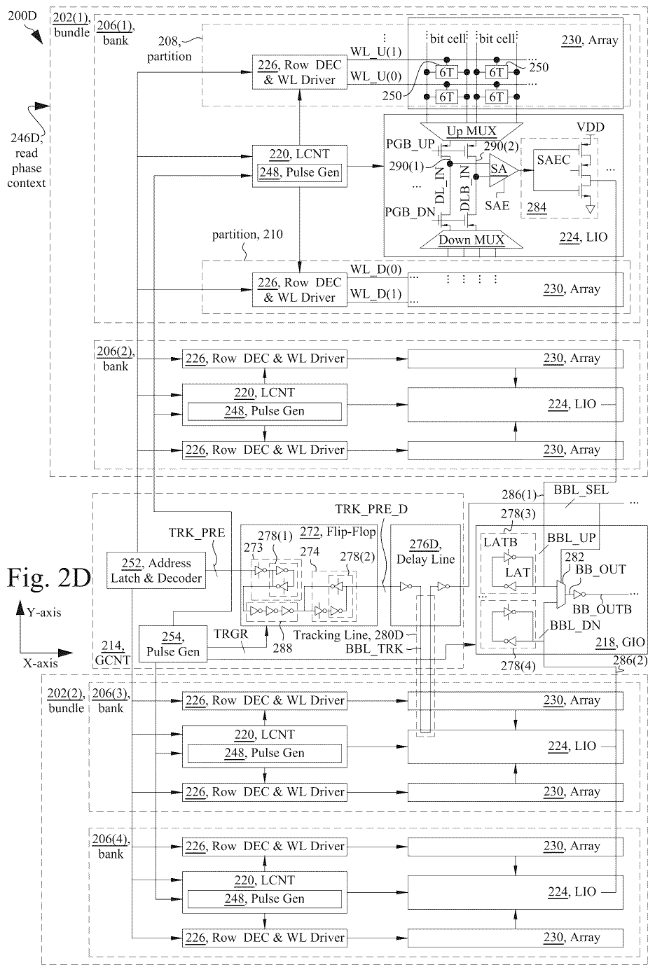

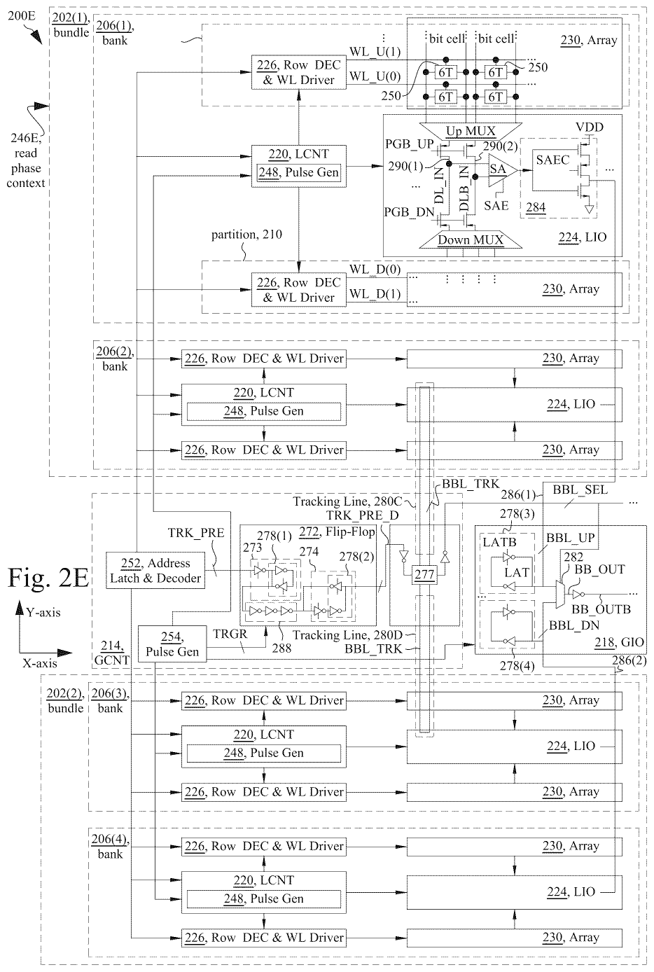

In FIG. 1, memory 100 includes banks 106(1), 106(2), 106(3) and 106(4) of memory cells (see FIG. 2A) that are stacked correspondingly on or over each other relative to a first direction, e.g., parallel to the Y-axis. FIG. 1 assumes the following: bank 106(1) is stacked on bank 106(2) such that bank 106(1) abuts bank 106(2); and bank 106(3) is stacked on bank 106(4). In some embodiments, bank 106(1) is stacked over bank 106(2) such that bank 106(1) substantially is not abutting bank 106(2) relative to the Y-axis. In some embodiments, bank 106(3) is stacked over bank 106(4).

Banks 106(1)-106(4) are organized into corresponding bundles 102(1) and 102(2). Bundle 102(1) is comprised of banks 106(1) and 106(2). Bundle 102(2) is comprised of banks 106(3) and 106(4). Bundle 102(1) is stacked over bundle 102(2) relative to the Y-axis. Bundle 102(1) is separated from bundle 102(2) by a global access manager 104, relative to the Y-axis. FIG. 1 assumes the following: bundle 102(1) is stacked on global access manager 104; and global access manager 104 is stacked on bundle 102(2). In some embodiments, bundle 102(1) is stacked over global access manager 104. In some embodiments, global access manager 104 is stacked over bundle 102(2).

In FIG. 1, each of banks 106(1)-106(4) includes a partition 108, a local access manager 112 and a partition 110. Relative to the Y-axis, for each of banks 106(1)-106(4): partition 108 is stacked over partition 110; and partition 108 is separated from partition 110 by local access manager 112. FIG. 1 assumes the following: partition 108 is stacked on access manager 112; and local access manager 112 is stacked on partition 110. In some embodiments, partition 108 is stacked over local manager 112. In some embodiments, local access manager 112 is stacked over partition 110.

Each partition 108 and each partition 110 includes an array 128 of memory cells, a row decoder & write line (WL) driver 126 and an array 130 of memory cells. Relative to a second direction (e.g., parallel to the X-axis) that is perpendicular to the first direction, and for each partition 108 and each partition 110, array 128 is separated from array 130 by row decoder & WL driver 126. FIG. 1 assumes the following: array 128 abuts row decoder & WL driver 126; and row decoder & WL driver 126 abuts array 130. In some embodiments, array 128 is proximal to row decoder & WL driver 126 but substantially does not abut row decoder & WL driver 126. In some embodiments, row decoder & WL driver 126 is proximal to array 130 but row decoder & WL driver 126 substantially does not abut array 130. In some embodiments, the first second directions correspond to perpendicular directions other than the Y-axis and the X-axis.

In some embodiments, for each of banks 106(1)-106(4), and relative to an axis 142 of symmetry: array 128 of partition 110 is mirror symmetric with respect to array 128 of partition 108; and array 130 of partition 110 is mirror symmetric with respect to array 130 of partition 108. In some embodiments, axis 142 is referred to as a local fold line 142. In some embodiments, each of banks 106(1)-106(4) is described as being folded at the partition-level. In some embodiments, each of banks 106(1)-106(4) is described as exhibiting partition-level folding.

In some embodiments, relative to an axis 140 of symmetry, bundle 102(2) is symmetric with respect to bundle 102(1) in terms of banks 106(1)-106(4), and in terms of partitions 108 and 110. However, relative to an axis 140 of symmetry, bundle 102(2) is not symmetric with respect the orientations of arrays 128 and 130. In some embodiments, axis 140 is referred to as a global fold line 140. In some embodiments, in light of fold lines 140 and 142, memory 100 is referred to as a folded memory 100. In some embodiments, memory 100 is described as being folded at the bundle-level. In some embodiments, memory 100 is described as exhibiting bundle-level folding.

In FIG. 1, each local access manager 112 includes a local input/output (I/O) circuit 122, a local controller (LCNT) 120 and a local I/O circuit (LIO) 124. Relative to the X-axis, LIO 122 is separated from LIO 124 by LCNT 120. FIG. 1 assumes the following: LIO 122 abuts LCNT 120; and LCNT 120 abuts LIO 124. In some embodiments, LIO 122 is proximal to LCNT 120 but substantially does not abut LCNT 120. In some embodiments, LCNT 120 is proximal to LIO 124 but LCNT 120 substantially does not abut LIO 124.

For each of banks 106(1)-106(4), LIO 122 is coupled to array 128 in corresponding partition 108 and to array 128 in corresponding partition 110 by signal lines including bank-wide access lines 132(1) and 132(2) (see FIG. 2A). Access lines 132(1) and 132(2) are intra-bank access lines. For simplicity of illustration, not all of such signal lines, including not all of bank-wide access lines 132(1) nor all of bank-wide access lines 132(2), are shown in FIG. 1. Bank-wide access lines 132(1) and 132(2) include write lines and read lines, or the like.

For each of banks 106(1)-106(4), LIO 124 is coupled to array 130 in corresponding partition 108 and to array 130 in corresponding partition 110 by signal lines including bank-wide access lines 132(1) and 132(2) (see FIG. 2A). Access lines 132(1) and 132(2) are intra-bank access lines. For simplicity of illustration, not all of such signal lines, including not all of bank-wide access lines 132(1) nor all of bank-wide access lines 132(2), are shown in FIG. 1.

Global access manager 104 includes a global I/O (GIO) circuit 116, a global controller (GCNT) 114 and a GIO circuit 118 of. Relative to the X-axis, GIO circuit 116 is separated from GIO circuit 118 by GCNT 114. FIG. 1 assumes the following: GIO circuit 116 abuts GCNT 114; and GCNT 114 abuts GIO circuit 118. In some embodiments, GIO circuit 116 is proximal to GCNT 114 but substantially does not abut GCNT 114. In some embodiments, GCNT 114 is proximal to GIO circuit 118 but GCNT 114 substantially does not abut GIO circuit 118.

In FIG. 1, global access manager 104 is separately coupled to bundle 102(1) and bundle 102(2). More particularly, regarding bundle 102(1), GIO 116 is coupled to each of LIO 122 in bank 106(1) and LIO 122 in bank 106(2) by signal lines including bundle-wide access lines 134(1) and 134(2) (see FIG. 2A). Access lines 134(1) and 134(2) are intra-bundle signal lines in that access lines 134(1) and 134(2) do not extend into another bundle, e.g., bundle 102(2). For simplicity of illustration, not all of such signal lines, including not all of bundle-wide access lines 134(1) nor all of bundle-wide access lines 134(2), are shown in FIG. 1. Bundle-wide access lines 134(1) and 134(2) include write lines and read lines, or the like.

Regarding bundle 102(2), GIO 118 is coupled to each of LIO 124 in bank 106(3) and LIO 124 in bank 106(4) by signal lines including bundle-wide access lines 136(1) and 136(2) (see FIG. 2A). Access lines 136(1) and 136(2) are intra-bundle access lines in that access lines 136(1) and 136(2) do not extend into another bundle, e.g., bundle 102(1). For simplicity of illustration, not all of such signal lines, including not all of bundle-wide access lines 136(1) nor all of bundle-wide access lines 136(2), are shown in FIG. 1. Bundle-wide access lines 136(1) and 136(2) include write lines and read lines, or the like.

Consider a memory according to another approach that is a counterpart to memory 100 and that includes banks that are counterparts to banks 106(1)-106(4), GIO circuits that are counterparts to GIO circuits 116 and 118, a GCNT that is a counterparts to GCNT 114, and LIOs that are counterparts to LIOs 122 and 124. Each counterpart GIO circuit is coupled to the counterpart GIO by memory-wide signal lines. Because each of the memory-wide signal lines according to the other approach are coupled to each of the counterpart LIOs, the memory-wide signal lines according to the other approach extend into all the counterpart banks such that the memory-wide signal lines according to the other approach are long.

As part of developing at least some of the present memories, one or more of the present inventors recognized at the least the following: because the memory-wide signal lines according to the other approach are long, consequently the memory-wide signal lines according to the other approach experience significant resistive-capacitive (RC) loading which reduces signal propagation speeds, degrades signal quality and increases power consumption, or the like; about 20% of the power consumed during a read phase in the operation of the counterpart memory, for example, is consumed by the global bit line of counterpart memory; and there was an opportunity to reduce signal line lengths as compared to the memory according to another approach. Accordingly, at least some of the present embodiments, e.g., memory 100, reduce the lengths of access lines by using bundle-wide access lines, e.g., bundle-wide access lines 134(1)-134(2) and 136(1)-136(2), which improves signal propagation speeds, improves signal quality and reduces power consumption, or the like, as compared to the use of memory-wide signal lines in the memory according to another approach. In some embodiments, memory 100 reduces power consumption by about 13% as compared to the memory according to another approach. In some embodiments, the use of bundle-wide access lines 134(1)-134(2) and 136(1)-136(2) by GIO 118 reduces power consumption associated with the same by about 19% as compared to the power consumption associated with the use of the memory-wide signal lines by the counterpart GIO according to the other approach.

FIG. 2A is a schematic diagram of zoomed-in portion 246A of a memory 200A, in accordance with some embodiments.

Memory 200A is an example of memory 100 of FIG. 1. By being a zoomed-in portion, portion 246A is more detailed than the corresponding portion of FIG. 1. FIG. 2A is similar to FIG. 1. For brevity, the discussion will focus on differences of FIG. 2A as compared to FIG. 1 rather than on similarities. Components in FIG. 2A that are similar to components in FIG. 1 use 2-series numbering that is similar to the 1-series numbering of the corresponding components in FIG. 1.

FIG. 2A assumes a context of at least a portion of a write phase in the operation of memory 200A. Memory 200A includes: bundle 201; banks 206(1)-206(2); instances of partition 208; instance of partition 210; instances of LCNT 220; instances of LIO 224; instances of row decoder & WL driver 226; instances of array 230; a GCNT 214; and a GIO 218. For simplicity of illustration, only one instance of partition 208 and only one instance of partition 210 are called out with reference numbers.

Some of the components in FIG. 2A, e.g., GCNT 214, GIO 218, instances of LCNT 220, one of the instances of LIO 224, and one of the instances of array 230 are shown as including internal components that are relevant to at least a portion of a write phase in the operation of memory 200A. For simplicity of illustration, other internal components of GCNT 214, GIO 218, the instances of LCNT 220, the instance of LIO 224 in bank 206(1), and the instance of array 230 in partition 208 of bank 206(1) are not shown. In general, components in FIG. 2A which are not active in the context of the at least the portion of the write phase being discussed are shown using grayed out formatting. In FIG. 2A, each instance of LCNT 220 includes a corresponding instance of a pulse generator 248.

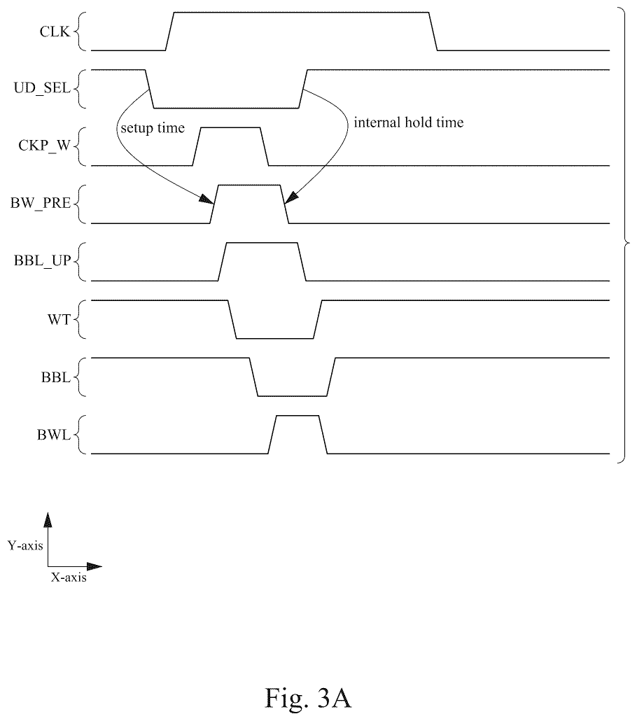

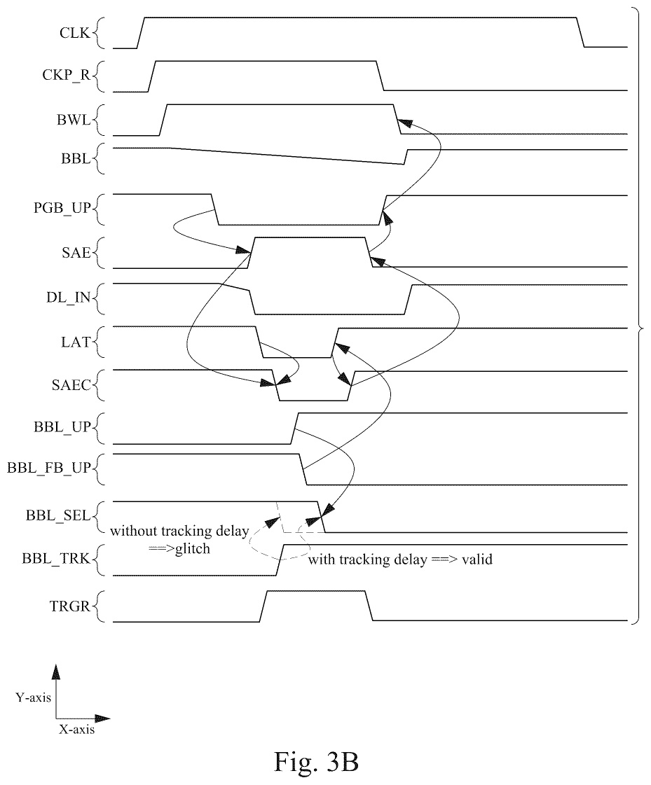

Each instance of LIO 224 in bundle 202(1) is coupled to GIO 218 by bundle-wide write lines 260(1) and 260(2). Each instance of LIO 224 in bundle 202(2) is coupled to GIO 218 by bundle-wide write lines 260(3) and 260(4). Bundle-wide write line 260(1) carries a bundle write data signal BW_UP (see FIG. 3A) that is generated by GIO 218 (discussed below). Bundle-wide write line 260(2) carries a bundle write data signal BW_UP_bar that is generated by GIO 218 (discussed below). Bundle write data signal BW_UP_bar is the inverse of bundle write data signal BW_UP. Bundle-wide write line 260(3) carries a bundle write data signal BW_DN that is generated by GIO 218 (discussed below). Bundle-wide write line 260(4) carries a bundle write data signal BW_DN_bar that is generated by GIO 218. Bundle write data signal BW_DN_bar is the inverse of bundle write data signal BW_DN.

In FIG. 2A, the instance of array 230 in partition 208 of bank 206(1) includes instances of a bit cell 250. In FIG. 2A, bit cell 250 is assumed to be a six transistor (6T) static random access memory (SRAM) cell. In some embodiments, bit cell 250 is an SRAM bit cell that includes a number of transistors other than six. In some embodiments, bit cell 250 is a type of bit cell other than an SRAM bit cell. Regarding the instance of row decoder & WL driver 226 in partition 208 of bank 206(1), instances of word lines (WLs) WL_U(0), WL_U(1), . . . , couple the instance of row decoder & WL driver 226 to corresponding instances of bit cell 250 in partition 208 of bank 206(1).

The instance of LIO 224 in bank 206(1) in FIG. 2A includes a first upper (up) multiplexer (MUX) and a first lower (or down) MUX. The first up MUX is coupled to the instances of bit cell 250 in array 230 of partition 208. The first down MUX is coupled to instances (not shown) of bit cell 250 in array 230 of partition 210.

Each of the first up MUX and the first down MUX is coupled to bundle-wide write line 260(1) through a first inverter. That is, each of the first up MUX and the first down MUX is coupled to an output of the first inverter; and the input of the first inverter is coupled to bundle-wide write line 260(1). The first inverter inverts bundle write data signal BW_UP, and the inverted version of bundle write data signal BW_UP is referred to as local write data signal WT (see FIG. 3A).

Each of the first up MUX and the first down MUX is also coupled to bundle-wide write line 260(2) through a second inverter. That is, each of the first up MUX and the first down MUX is coupled to an output of the second inverter; and the input of the second inverter is coupled to bundle-wide write line 260(2). The second inverter inverts bundle write data signal BWB_UP, and the inverted version of bundle write data signal BWB_UP is referred to as local write data signal WC.

In FIG. 2A, GCNT 214 includes an address latch & decoder (AL&D) circuit 252 and a pulse generator 254. Each of AL&D circuit 252 and pulse generator 254 is configured to provide one or more corresponding signals to GIO 218.

A signal line 262(1) couples AL&D circuit 252 to each of the following: each instance of LCNT 220 in bundle 206(1); each instance of LCNT 220 in bundle 206(2); each instance of row decoder & WL driver 226 in bundle 206(1); and each instance of row decoder & WL driver 226 in bundle 206(2). Signal line 262(1) is a memory-wide signal line in that signal line 262(1) extends beyond a single bundle into at least one other bundle. FIG. 2A assumes that signal line 262(1) extends into all bundles, i.e., into bundles 206(1) and 206(2).

A signal line 262(2) couples pulse generator 254 to each of the following: each instance of LCNT 220 in bundle 206(1); and each instance of LCNT 220 in bundle 206(2). Signal line 262(2) is a memory-wide signal line. FIG. 2A assumes that signal line 262(2) extends into all bundles, i.e., into bundles 206(1) and 206(2).

In FIG. 2A, GIO 218 includes: selection gates 256(1), 256(2), 256(3) and 256(4); and drivers 258(1), 258(2), 258(3) and 258(4). FIG. 2A assumes that each of drivers 258(1)-258(4) is an inverter. In some embodiments, drivers 258(1)-258(4) are correspondingly comprised of one or more components that are different than that of FIG. 2A. Inverter 258(1) is coupled between selection gate 256(1) and bundle-wide write line 260(1). Inverter 258(2) is coupled between selection gate 256(2) and bundle-wide write line 260(2). Inverter 258(3) is coupled between selection gate 256(3) and bundle-wide write line 260(3). Inverter 258(4) is coupled between selection gate 256(4) and bundle-wide write line 260(4). FIG. 2A assumes that each of selection gates 256(1)-256(4) is a corresponding AND gate. In some embodiments, selection gates 256(1)-256(4) are correspondingly comprised of arrangements of logic gates other than that shown in FIG. 2A.

Selection gate 256(1) is configured to receive first bundle-discerning signals. The first bundle-discerning signals are represented by a combination of signals including a choice signal BW_PRE (see FIG. 3A) and a choice signal UD_SELB. Choice signal UD_SELB is the inverse of a choice signal UD_SEL (see FIG. 3A). In some embodiments, choice signals UD_SEL and UD_SELB are generated by AL&D circuit 252.

Selection gate 256(2) is configured to receive second bundle-discerning signals. The second bundle-discerning signals are represented by a combination of signals including choice signal UD_SELB and a choice signal BWB_PRE. Choice signal BWB_PRE is the inverse of choice signal BWB_PRE. In some embodiments, choice signals BW_PRE and BWB_PRE are generated by AL&D circuit 252.

Selection gate 256(3) is configured to receive third bundle-discerning signals. The third bundle-discerning signals are represented by a combination of signals including choice signal BW_PRE and choice signal UD_SEL. Selection gate 256(4) is configured to receive fourth bundle-discerning signals. The fourth bundle-discerning signals are represented by a combination of signals including choice signal BWB_PRE and choice signal UD_SEL.

Based on the first to fourth bundle-discerning signals, GIO 218 uses selection gates 256(1)-256(4) to selectively access bundles 202(1) and 202(2) on a mutually exclusive basis. GIO 218 either (A) accesses bundle 202(1) but not bundle 202(2) or (B) accesses bundle 202(2) but not bundle 202(1). In other words, based on the combinations of choice signals UD_SEL, UD_SELB, BW_PRE or BWB_PRE noted above, GIO 218 uses selection gates 256(1)-256(4) to selectively access bundles 202(1) and 202(2) on a mutually exclusive basis. The at least the portion of the write phase in the operation of memory 200A discussed in the context of FIG. 2A is additionally discussed in the context of FIG. 3A (see below).

FIG. 2B is a schematic diagram of zoomed-in portion 246B of a memory 200B, in accordance with some embodiments.

Memory 200B is an example of memory 100 of FIG. 1. By being a zoomed-in portion, portion 246B is more detailed than the corresponding portion of FIG. 1. FIG. 2B is similar to FIG. 1 and to FIG. 2A. For brevity, the discussion will focus on differences of FIG. 2B as compared to FIGS. 1 and 2A rather than on similarities. As with FIG. 2A, components in FIG. 2B that are similar to components in FIG. 1 use 2-series numbering that is similar to the 1-series numbering of the corresponding components in FIG. 1.

FIG. 2B assumes a context of at least a portion of a read phase in the operation of memory 200B whereas FIG. 2A assumes a context of at least a portion of a write phase in the operation of memory 200A. In some embodiments, memory 200B is the same as memory 200A with the differences in terms of components shown in FIG. 2A versus FIG. 2B arising from drawing simplifications that reflect the corresponding read phase and write phase contexts.

The instance of LIO 224 in bank 206(1) in FIG. 2B includes a second up MUX and a second down MUX. It is to be called that the instance of LIO 224 in bank 206(1) in FIG. 2A includes: the first up MUX and the first down MUX. The instance of LIO 224 in bank 206(1) in FIG. 2B further includes a sense amplifier SA and a selective pull-up/pull-down circuit 284.

The second up MUX is coupled to a bank data line 290(1) and a bank data line 290(2) by corresponding first pass gates that are correspondingly controlled by a pass gate control signal PGB_UP (see FIG. 3B). Control signal PGB_UP is the inverse of a pass gate control signal PG_UP. FIG. 2B assumes that the first pass gates for the second up MUX are field-effect transistors (FETs), and more particularly positive-channel metal oxide semiconductor (PMOS) FETs (PFETs). Accordingly, control signal PGB_UP is provided to the PFETs rather than control signal PG_UP.

The second up MUX is coupled to the instances of bit cell 250 in array 230 of partition 208. The second down MUX is coupled to instances (not shown) of bit cell 250 in array 230 of partition 210. The second down MUX is also coupled to bank data line 290(1) and bank data line 290(2) albeit by corresponding second pass gates that are correspondingly controlled by a pass gate control signal PGB_DN. Control signal PGB_DN is the inverse of a pass gate control signal PG_DN. FIG. 2B assumes that the second pass gates for the second down MUX are PFETs. Accordingly, control signal PGB_DN is provided to the PFETs rather than control signal PG_UP.

In memory 200B, inputs of sense amplifier SA are correspondingly coupled to bank data line 290(1) and bank data line 290(2) by which corresponding bank data signals DL_IN and DLB_IN are received by sense amplifier SA. FIG. 2B assumes that control signal PGB_DN is the inverse of control signal PGB_UP so that the second down MUX and the second up MUX are mutually exclusively coupled to sense amplifier SA. Sense amplifier SA is coupled to a bundle-wide read line 286(1) by a selective pull-up/pull-down (SPUD) circuit 284. Sense amplifier SA is controlled by a sense amplifier control signal SAE. SPUD circuit 284 is controlled by a control signal SAEC.

In FIG. 2B, GIO 218 includes a multiplexer (MUX) 282. Inputs of MUX 282 correspondingly are coupled to bundle-wide read line 286(1) and a bundle-wide read line 286(2). As such, bundle-wide read line 286(1) couples each instance of LIO 224 in bundle 202(1) to GIO 218. Bundle-wide read line 286(2) couples each instance of LIO 224 in bundle 202(2) to GIO 218. Accordingly, MUX 282 is configured to receive: a bundle bit line signal BBL_UP on bundle-wide read line 286(1); and a bundle bit line signal BBL_DN on bundle-wide read line 286(2). Based on a first state of a MUX enable signal MUX_EN (not shown), MUX 282 is enabled to make a selection between bundle bit line signal BBL_UP and bundle bit line signal BBL_DN according to a control signal BBL_SEL (discussed below), and output the selected signal as bundle bit output signal BB_OUT. The output of MUX 282 is coupled to an inverter which is configured to generate an inverted version of bundle bit output signal BB_OUT referred to as bundle bit bar output signal BB_OUTB. Based on a second state of MUX enable signal MUX_EN, MUX 282 is disabled from being able to make a selection between bundle bit line signal BBL_UP or bundle bit line signal BBL_DN.

GIO 218 further includes latches 278(3) and 278(4). Each of latches 278(3) and 278(4) includes a tri-state inverter and an inverter coupled in a loop. In each of latches 278(3) and 278(4), the tri-state inverter is configured to receive a latch signal LAT and a latch signal LATB. Latch signal LATB is the inverse of latch signal LAT.

In FIG. 2B, GCNT 214 includes: AL&D circuit 252; a pulse generator 254; a flip-flop (FF) 272; and a delay line 276B. In general, FF 272 is configured to receive a bundle bit line tracking precursor signal TRK_PRE from AL&D circuit 252 and output a delayed version of signal TRK_PRE referred to herein as signal TRK_PRE_D. In general, delay line 288 is configured to receive signal TRK_PRE_D from FF 272 and generate control signal BBL_SEL.

FF 272 includes: a leader latch 273; a follower latch 274; and a delay line 288. Leader latch 273 includes a first tri-state inverter coupled in series with an internal latch 278(1), where internal latch 278(1) includes a second tri-state inverter and an inverter coupled in a first loop. In some embodiments, leader latch 273 is referred to as being a sleepy type of latch in that leader latch 278(1) selectively can be put into a sleep mode by coordinating the operational states of the first and second tri-state inverters. In some embodiments, leader latch 273 is referred to as a tri-state inverter.

Follower latch 274 includes a tri-state inverter coupled in series with an internal latch 278(2), where internal latch 278(2) includes a fourth tri-state inverter and an inverter coupled in a second loop. In some embodiments, follower latch 274 is referred to as being a sleepy type of latch in that follower latch 278(2) selectively can be put into a sleep mode by coordinating the operational states of the third and fourth tri-state inverters. In some embodiments, follower latch 274 is referred to as a tri-state inverter.

Delay line 288 is coupled in series between leader latch 273 and follower latch 274. Delay line 288 includes one or more inverters coupled in series. FIG. 2B assumes that the number of inverters which comprise delay line 288 is three. In some embodiments, delay line 288 is comprised of a number of inverters other than three according to a size of the delay to be induced by delay line 288. In some embodiments, delay line 288 is something other than an inverter-based circuit.

Leader latch 273 is configured to receive signal TRK_PRE and generate a first delayed version of signal TRK_PRE. Delay line 288 is configured to receive the first delayed version of signal TRK_PRE and generate a second delayed version of signal TRK_PRE. Follower latch 274 is configured to receive the second delayed version of signal TRK_PRE and generate a third delayed version of signal TRK_PRE, where the third delayed version of signal TRK_PRE represents signal TRK_PRE_D.

FF 272 is configured to receive a trigger signal TRGR (see FIG. 3B) from pulse generator 254. In some embodiments, trigger signal TRGR controls follower latch 274 to receive the second delayed version of signal TRK_PRE and output the third delayed version of signal TRK_PRE. In some embodiments, the outputting of the third delayed version of signal TRK_PRE, i.e., the generating of signal TRK_PRE_D, is represented by changing the state of signal TRK_PRE_D. In some embodiments, trigger signal TRGR (see FIG. 3B) changes from a state representing a logical zero to a state representing a logical one, which is followed by signal TRK_PRE_D (not shown in FIG. 3A) changing from logical zero to logical one, which is followed by a tracking signal BBL_TRK (discussed below; also see FIG. 3B) changing from logical zero to logical one.

An FF enable signal FF_EN (not shown) controls an active state of FF 272. For example: when FF enable signal FF_EN transitions to an active state, then FF 272 is rendered active; and when FF enable signal FF_EN transitions to an inactive state, then FF 272 is rendered inactive. The FF enable signal FF_EN transitions to the active state, e.g., at the beginning of the read phase in the operation of memory 200B. The FF enable signal FF_EN transitions to the active state, e.g., at the beginning of in the read phase in the operation of memory 200B.

MUX 282 is enabled to make a selection between bundle bit line signal BBL_UP and bundle bit line signal BBL_DN according to a control signal BBL_SEL (discussed below). The output of MUX 282 (discussed below) is coupled to an inverter. Based on the second state of MUX enable signal MUX_EN, MUX 282 is disabled from being able to make a selection between bundle bit line signal BBL_UP or bundle bit line signal BBL_DN.

Delay line 276B includes a tracking line 280B coupled in series between a first inverter and a second inverter. The first inverter receives signal TRK_PRE_D and generates tracking signal BBL_TRK, where the latter is a delayed and inverted version of the former. The second inverter receives tracking signal BBL_TRK and generates control signal BBL_SEL, the latter being a delayed and inverted version of the former.

In some embodiments, tracking line 280B is a signal path comprised of one or more conductive segments. As tracking signal BBL_TRL propagates along tracking line 280B, the cumulative length of the one or more conductive segments, i.e., the length of tracking line 280B, induces a delay in tracking signal BBL_TRK. As control signal BBL_SEL is the inversion of tracking signal BBL_TRK, the delay in tracking signal BBL_TRK induces a corresponding delay in control signal BBL_SEL.

The length of tracking line 280B is selected so that the delay tracking signal BBL_TRK causes control signal BBL_SEL to change state after either (A) bundle bit line signal BBL_UP has finished changing state in the context of bundle 202(1) being accessed or (B) bundle bit line signal BBL_DN has finished changing state in the context of bundle 202(1) being accessed, resulting in valid operation. However, if the length of tracking line 280B is insufficient, then delay tracking signal BBL_TRK will not cause a sufficient delay in control signal BBL_SEL such that control signal BBL_SEL changes state before either (A) bundle bit line signal BBL_UP has finished changing state in the context of bundle 202(1) being accessed or (B) bundle bit line signal BBL_DN has finished changing state in the context of bundle 202(1) being accessed, resulting in invalid operation, i.e., resulting in a glitch. FIG. 2B further assumes that bundles 202(1) and 202(2) are substantially symmetric such that the propagation delay experienced by bundle bit line signal BBL_UP on bundle-wide read line 286(1) is substantially the same as the propagation delay experienced by bundle bit line signal BBL_DN on bundle-wide read line 286(2). Regarding a context in which bundle 202(1) and 202(2) are substantially asymmetric such that the propagation delay experienced by bundle bit line signal BBL_UP on bundle-wide read line 286(1) is substantially different than the propagation delay experienced by bundle bit line signal BBL_DN on bundle-wide read line 286(2), see FIG. 2E, or the like.

In some embodiments, the length of tracking line 280B, L_280, is about one-half the length of bundle-wide read line 286(1), L_286(1), such that L_280˜½*L_286(1).

The length of bundle-wide read line 286(1) is substantially equal to the length of bundle-wide read line 286(2) such that the L_286(2)≡L_286(1), and where the symbol≡is used herein to denote substantially equal. As used herein, substantially equal is understood to be more equal than approximately equal, i.e., being substantially equal is understood to represent a smaller difference than is understood to be represented by being approximately equal. As used herein, substantially equal is understood as covering a first range of differences and approximately equal is understood as covering a second range of differences, where the second range is larger than the first range and the second range includes the first range. Accordingly, the length of tracking line 280B also is about one-half the length of bundle-wide read line 286(2), such that L_280˜½*L_286(2).

Based on control signal BBL_SEL, GIO 218 uses MUX 282 to selectively access bundles 202(1) and 202(2) on a mutually exclusive basis. GIO 218 either (A) accesses bundle 202(1) but not bundle 202(2) or (B) accesses bundle 202(2) but not bundle 202(1). The at least the portion of the read phase in the operation of memory 200B discussed in the context of FIG. 2B is additionally discussed in the context of FIG. 3B (see below).

FIG. 2C is a schematic diagram of zoomed-in portion 246C of a memory 200C, in accordance with some embodiments.

Memory 200C of FIG. 2C is a version of memory 200B of FIG. 2B; as such, memory 200C is an example of memory 100 of FIG. 1. For brevity, the discussion will focus on differences of FIG. 2C as compared to FIG. 2B rather than on similarities.

In FIG. 2C, delay line 276C and tracking line 280C have correspondingly replaced delay line 276B and tracking line 280B of FIG. 2B.

In some embodiments, the length of tracking line 280C is sufficient to extend into one of the instances of LIO 224 in bundle 202(1). In FIG. 2C, as an example, it is assumed that the length of tracking line 280C is sufficient to extend into the instance of LIO 224 in bank 206(2) of bundle 202(1).

FIG. 2C assumes that bundles 202(1) and 202(2) are substantially symmetric such that the propagation delay experienced by bundle bit line signal BBL_UP on bundle-wide read line 286(1) is substantially the same as the propagation delay experienced by bundle bit line signal BBL_DN on bundle-wide read line 286(2). Regarding a context in which bundle 202(1) and 202(2) are substantially asymmetric such that the propagation delay experienced by bundle bit line signal BBL_UP on bundle-wide read line 286(1) is substantially different than the propagation delay experienced by bundle bit line signal BBL_DN on bundle-wide read line 286(2), see FIG. 2E, or the like.

FIG. 2D is a schematic diagram of zoomed-in portion 246D of a memory 200D, in accordance with some embodiments.

Memory 200D of FIG. 2D is a version of memory 200B of FIG. 2B; as such, memory 200D is an example of memory 100 of FIG. 1. For brevity, the discussion will focus on differences of FIG. 2D as compared to FIG. 2B rather than on similarities.

In FIG. 2D, delay line 276D and tracking line 280D have correspondingly replaced delay line 276B and tracking line 280B of FIG. 2B, or the like.

In some embodiments, the length of tracking line 280D is sufficient to extend into one of the instances of LIO 224 in bundle 202(2). In FIG. 2D, as an example, it is assumed that the length of tracking line 280D is sufficient to extend into the instance of LIO 224 in bank 206(3) of bundle 202(2).

FIG. 2D assumes that bundles 202(1) and 202(2) are substantially symmetric such that the propagation delay experienced by bundle bit line signal BBL_UP on bundle-wide read line 286(1) is substantially the same as the propagation delay experienced by bundle bit line signal BBL_DN on bundle-wide read line 286(2). Regarding a context in which bundle 202(1) and 202(2) are substantially asymmetric such that the propagation delay experienced by bundle bit line signal BBL_UP on bundle-wide read line 286(1) is substantially different than the propagation delay experienced by bundle bit line signal BBL_DN on bundle-wide read line 286(2), see FIG. 2E, or the like.

FIG. 2E is a schematic diagram of zoomed-in portion 246D of a memory 200D, in accordance with some embodiments.

Memory 200E of FIG. 2E is a version of memory 200B of FIG. 2B; as such, memory 200E is an example of memory 100 of FIG. 1. For brevity, the discussion will focus on differences of FIG. 2E as compared to FIG. 2B rather than on similarities. In some embodiments, FIG. 2E is described as a combination of FIGS. 2C and 2D.

In FIG. 2E: delay lines 276C of FIGS. 2C and 276D of FIG. 2D have replaced delay line 276B of FIG. 2B; and tracking lines 280C of FIGS. 2C and 280D of FIG. 2D have replaced tracking line 280B of FIG. 2B. As compared to delay lines 276C and 276D correspondingly of FIGS. 2C-2D, delay line 276E of FIG. 2E further includes a switch 277 configured to selectively couple tracking line 280C or tracking line 280D between the first inverter and the second inverter of delay line 276E.

FIG. 2E assumes that bundles 202(1) and 202(2) are substantially asymmetric such that the propagation delay experienced by bundle bit line signal BBL_UP on bundle-wide read line 286(1) is substantially different than the propagation delay experienced by bundle bit line signal BBL_DN on bundle-wide read line 286(2). In FIG. 2E, as an example, the following is assumed: the length of tracking line 280C is substantially different than the length of tracking line 280D. More particularly, the example of FIG. 2E assumes that the length of tracking line 280C is sufficient to extend all the way across the instance of LIO 224 in bank 206(2) of bundle 202(1); and the length of tracking line 280D is sufficient to extend slightly into the instance of LIO 224 in bank 206(3) of bundle 202(2). Regarding a context in which bundle 202(1) and 202(2) are substantially symmetric such that the propagation delay experienced by bundle bit line signal BBL_UP on bundle-wide read line 286(1) is substantially the same as the propagation delay experienced by bundle bit line signal BBL_DN on bundle-wide read line 286(2), see FIGS. 2B-2D, or the like.

FIG. 3A is a timing diagram, in accordance with some embodiments.

The timing diagram of FIG. 3A includes waveforms related to at least the portion of the write phase in the operation of memory 200A discussed in the context of FIG. 2A.

More particularly, the timing diagram of FIG. 3A includes the following waveforms: a waveform representing a clock CLK; a waveform representing choice signal UD_SEL; a waveform representing a clock CKP_W; a waveform representing a bundle write precursor signal BW_PRE; a waveform representing bundle-wide write data signal BW_UP; a waveform representing local write data signal WT a waveform representing bundle bit line control signal BBL; and a waveform representing bundle word line signal BWL. Clock signal CLK is a global clock signal. Clock signal CKP_W is a write-phase signal based on clock signal CLK.

FIG. 3B is a timing diagram, in accordance with some embodiments.

The timing diagram of FIG. 3B includes waveforms related to at least the portion of the read phase in the operation of memory 200B discussed in the context of FIG. 2B.

More particularly, the timing diagram of FIG. 3B includes the following waveforms: a waveform representing clock CLK; a waveform representing a clock CKP_R; a waveform representing bundle word line signal BWL, a waveform representing bundle bit line control signal BBL; a waveform representing pass gate control signal PGB_UP; a waveform representing sense amplifier control signal SAE; a waveform representing bank data signal DL_IN; a waveform representing latch signal LAT; a waveform representing control signal SAEC; a waveform representing bundle bit line signal BBL_UP; a waveform representing a feedback signal BBL_FB_UP that is based on signal BBL_UP; a waveform representing control signal BBL_SEL; a waveform representing tracking signal BBL_TRK; and a waveform representing trigger signal TRGR.

Clock signal CKP_R is a read phase signal based on clock signal CLK. Signal BBL_FB_UP is an inverted and delayed version of signal BBL_FB_UP. Once feedback signal BBL_FB_UP has become stable, it is indicative that signal BBL_UP has become stable, and then latch 278(3) is opened, i.e., is activated to store the value of signal BBL_UP.

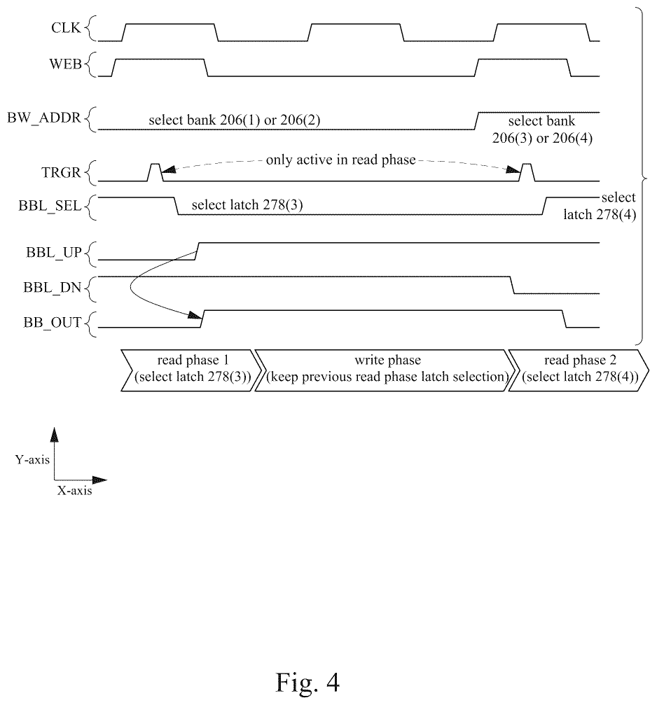

FIG. 4 is a timing diagram, in accordance with some embodiments.

The timing diagram of FIG. 4 includes waveforms related to at least the portion of the write phase in the operation of memory 200B discussed in the context of FIG. 2A and to at least the portion of the read phase in the operation of memory 200B discussed in the context of FIG. 2B.

More particularly, the timing diagram of FIG. 4C includes the following waveforms: a waveform representing clock CLK; a waveform representing a write enable bar signal WEB; a waveform BW_ADDR representing whether (i) bank 206(1) or 206(2) of bundle 202(1) or (ii) bank 206(3) or 206(4)-of bundle 202(2) is being addressed; a waveform representing trigger signal TRGR; a waveform representing control signal BBL_SEL; a waveform representing bundle bit line signal BBL_UP; a waveform representing bundle bit line signal BBL_DN; and a waveform representing bundle bit output signal BB_OUT. Write enable bar signal WEB is the inverse of a write enable bar signal WE (not shown). In the example of FIG. 4, the following is assumed: during the first read phase, the latch selected is latch 278(3); during the write phase, the latch selected in the previous read phase is selected, namely latch 278(3); and during the second read phase, the latch selected is latch 278(4).

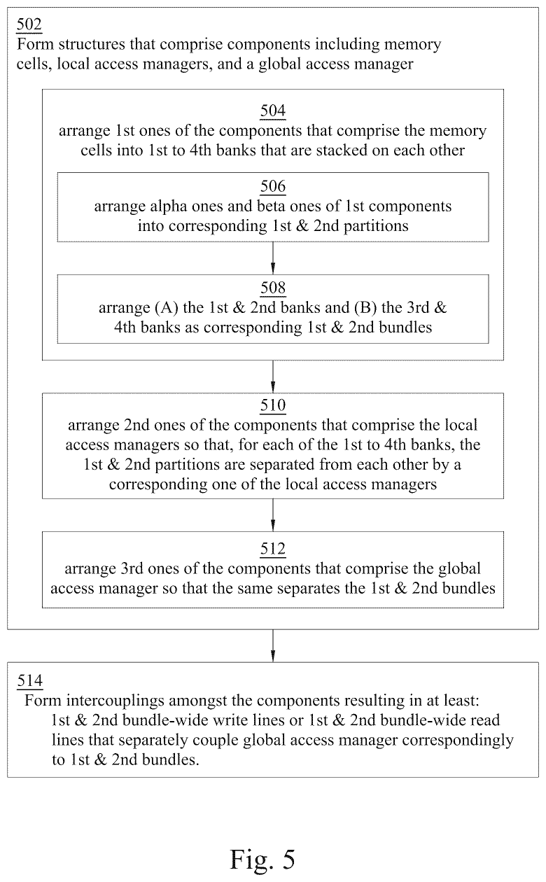

FIG. 5 is a flowchart 500 of a method of manufacturing a memory, in accordance with some embodiments.

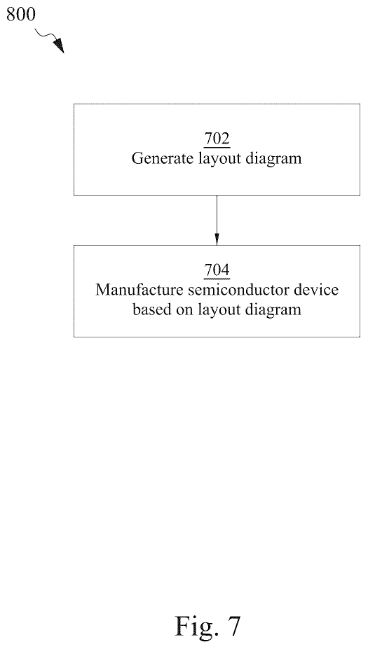

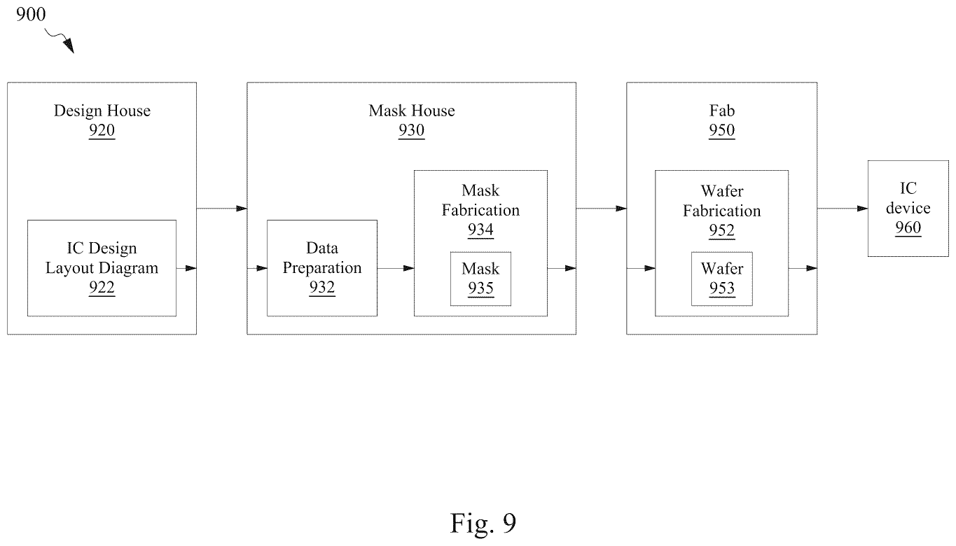

Flowchart 500 is an example of block 704 (see FIG. 7, discussed below). The method of flowchart 600 is implementable, for example, using IC manufacturing system 900 (see FIG. 9, discussed below), in accordance with some embodiments. Examples of a memory which can be manufactured according to the method of flowchart 500 include the memories disclosed herein, or the like. Flowchart 500 includes blocks 502-514.

At block 502, structures are formed that comprise components, the components including memory cells, local access managers and a global access manager. Examples of the structures that comprise the noted components are discussed below. Examples of the memory cells include bit cells 250 of FIGS. 2A-2B, or the like. Examples of the local access managers include instances of local access managers 112 of FIG. 1, or the like. An example of the global access manager is global access manager 104 of FIG. 1, or the like. Block 502 includes blocks 504-508. Within block 502, flow proceeds to block 504.

Regarding block 502, examples of the structures that comprise the noted components include structures that comprise semiconductor devices, e.g., transistors, structures that facilitate coupling to transistors, or the like. In some embodiments, the structures that comprise transistors and the structures that facilitate coupling to transistors are formed in one or more first layers that are referred to collectively as a transistor layer. Examples of the transistors include PFETs, negative-channel metal oxide semiconductor (NMOS) FETs (NFETs), or the like.

Regarding block 502, examples of structures that comprise transistors include: active regions in a semiconductor layer; well regions around selected ones of the active regions; source/drain (S/D) regions in active regions; channel regions in active regions between corresponding pairs of S/D regions; gate structures over corresponding ones of the active regions and (optionally) buried gate (BG) structures under corresponding ones of the active regions; or the like.

Regarding block 502, examples of structures that facilitate coupling to transistors include: metal-to-source/drain (MD) contacts that are over and couple to S/D regions and (optionally) counterpart buried MD (BMD) contacts that are under and couple to S/D regions; metal-to-gate (MG) contacts that couple to gate structures and (optionally) counterpart buried MG (BMG) contacts that couple to BG structures; via-to-MD (VD) contacts that couple to MD contacts and counterpart buried VD (BVD) contacts that couple to BMD contacts; via-to-MG (VG) contacts that couple to MG contacts and counterpart buried VG (BVG) contacts that couple to BMG contacts; local interconnect (LI) structures that couple, e.g., MD contacts and/or gate structures together and (optionally) buried LI (BLI) structures that couple, e.g., BMD contacts and/or BG gate structures together; or the like.

At block 504, first ones of the components that comprise the memory cells are arranged into first, second, third and fourth banks that are stacked on each other relative to a first direction. Examples of the first to fourth banks correspondingly include banks 106(1)-106(4) of FIG. 1 which are stacked on each other relative to the Y-axis, banks 206(1)-206(4) of FIGS. 2A-2B which are stacked on each other relative to the Y-axis, or the like. Block 506 includes blocks 506-508. Within block 504, flow proceeds to block 506.

At block 506, alpha ones and beta ones of the first components that comprise the memory cells are arranged into corresponding first and second partitions. Examples of the first and second partitions include partitions 108 and 110 correspondingly of each of banks 106(1)-106(4) of FIG. 1, or the like. From block 506, flow proceeds to block 508.

At block 508, the (A) first and second banks and (B) the third and fourth banks are arranged as corresponding first and second bundles. An example of the first bundle is bundle 102(1) of FIG. 1 which includes banks 106(1) and 106(2), or the like. An example of the second bundle is bundle 102(2) of FIG. 1 which includes banks 106(3) and 106(4), or the like. From block 508, flow exits block 504 and proceeds to block 510.

At block 510, second ones of the components that comprise the local access managers are arranged so that, for each of the first to fourth banks, the first and second partitions are separated from each other relative to the first direction. Examples of local access managers that separate corresponding first and second partitions include the instance of local access manager 112 that separates partitions 108 and 110 of bank 106(1) relative to the Y-axis, the instance of local access manager 112 that separates partitions 108 and 110 of bank 106(2) relative to the Y-axis, the instance of local access manager 112 that separates partitions 108 and 110 of bank 106(3) relative to the Y-axis, the instance of local access manager 112 that separates partitions 108 and 110 of bank 106(4) relative to the Y-axis, or the like. From block 512, flow exits block 502 and proceeds to block 514.

At block 514, intercouplings are formed amongst the components resulting in at least first & second bundle-wide write lines or first & second bundle-wide read lines that separately couple the global access manager to the first and second bundles. Examples of the first & second bundle-wide write lines include bundle-wide write lines 260(1) & 260(3) of FIG. 2A, bundle-wide write lines 260(3) & 260(4) of FIG. 2A, or the like. Examples of the first & second bundle-wide read lines include bundle-wide read lines 286(1) & 286(2) of FIG. 2B, or the like.

Regarding block 514, examples of forming intercouplings include forming routing segments and/or power grid (PG) segments in metallization layers which are correspondingly over and (optionally) under a transistor layer. The routing segments and PG segments are conductive. In some embodiments, segments are configured to carry signals including input/output (I/O) signals, control signals, or the like. In such embodiments, routing segments are coupled correspondingly to VD contacts, MG contacts, (optionally) BVD contacts, (optionally) BVG contacts, or the like. In some embodiments, PG segments are configured to be energized with corresponding ones of reference voltages of a power grid (PG). In such embodiments, PG segments are coupled correspondingly to VD contacts, MG contacts, (optionally) BVD contacts, (optionally) BVG contacts, or the like. For example, first ones of such PG segments are configured for energization with a first reference voltage, e.g., VDD, and second ones of such PG segments are configured for energization with a second reference voltage, e.g., VSS.

Regarding block 512, in some embodiments, the arranging third ones of the components that comprise the global access manager (e.g., 104) includes: configuring the global access manager (e.g., 104) to access the first (e.g., 102(1)) and second (e.g., 102(2)) bundles on a mutually exclusive basis.

Regarding block 502, in some embodiments, the forming structures that comprise components further includes: using alpha ones of the third components that comprise the global access manager (e.g., 104) to form first (e.g., 116) and second (e.g., 118) global I/O circuits; using beta ones of the third components that comprise the global access manager (e.g., 104) to form a global controller (e.g., 114); and arranging the beta ones of the third components that comprise the global access manager (e.g., 104) so that the global controller (e.g., 114) separates the first (e.g., 116) and second (e.g., 118) global I/O circuits relative to a second direction (e.g., X-axis) perpendicular to the first direction (e.g., Y-axis).

Regarding block 512, in some embodiments, the using beta ones of the third components that comprise the global access manager (e.g., 104) to form a global controller (e.g., 114), includes: arranging first ones of the beta components to comprise a first selection gate (e.g., 256(1)); arranging second ones of the beta components to comprise a second selection gate (e.g., 256(3)); arranging third ones of the beta components to comprise a first driver (e.g., 258(1)); and arranging fourth ones of the beta components to comprise a second driver (e.g., 258(3)). Also regarding block 512, in some embodiments, the forming (e.g., 604) intercouplings amongst the components further results in at least: the first selection gate (e.g., 256(1)) configured to receive first bundle-selection signals (e.g., UD_SELB+BW_PRE); the second selection gate (e.g., 256(3)) being configured to receive second bundle-selection signals (e.g., UD_SEL+BW_PRE); the first driver (e.g., 258(1)) being coupled between the first selection gate (e.g., 256(1)) and the first bundle-wide write line (e.g., 260(1)); and the second driver (e.g., 258(3)) being coupled between the second selection gate (e.g., 256(3)) and the second bundle-wide write line (e.g., 260(3)).

Also regarding block 512, in some embodiments: the first bundle-selection signals (e.g., UD_SELB+BW_PRE) include a first choice signal (e.g., UD_SELB) and a second choice signal (e.g., BW_PRE); and the second bundle-selection signals (e.g., UD_SEL+BW_PRE) include the second choice signal (e.g., BW_PRE) and a third choice signal (e.g., UD_SEL). Also regarding block 512, in some embodiments, the forming (e.g., 604) intercouplings amongst the components further results in at least: the first selection gate (e.g., 256(1)) being configured as a first AND gate and further being configured to receive the first choice signal (e.g., UD_SELB) and the second choice signal (e.g., BW_PRE); and the second selection gate (e.g., 256(3)) being configured as a second AND gate and further being configured to receive the second choice signal (e.g., BW_PRE) and the third choice signal (e.g., UD_SEL).

Regarding block 506, in some embodiments, the using beta ones of the third components that comprise the global access manager (e.g., 104) to form a global controller (e.g., 214) further includes: arranging fifth ones of the beta components to comprise a third selection gate (e.g., 256(2)); arranging sixth ones of the beta components to comprise a fourth selection gate (e.g., 256(4)); arranging seventh ones of the beta components to comprise a third driver (e.g., 258(2); and arranging eighth ones of the beta components to comprise a fourth driver (e.g., 258(4)). Also regarding block 512, in some embodiments, the forming (e.g., 604) intercouplings amongst the components further results in at least: third (e.g., 286(1)) and fourth (e.g., 260(4)) bundle-wide write lines that separately couple the global access manager (e.g., 104) correspondingly to the first (e.g., 102(1)) and second (e.g., 102(2)) bundles; the third selection gate (e.g., 256(2)) being operable to receive third selection signals (e.g., signal UD_SELB and GWB_PRE); the fourth selection gate (e.g., 256(4)) being operable to receive fourth selection signals (e.g., signal UD_SEL and signal GWB_PRE); the third driver (e.g., 258(2)) being coupled between the third selection gate (e.g., 256(2)) and the third bundle-wide write line (e.g., 286(1)); and the fourth driver (e.g., 258(4)) being coupled between the third selection gate (e.g., 256(4)) and the fourth bundle-wide write line (e.g., 260(4)).

Regarding block 506, in some embodiments, the using beta ones of the third components that comprise the global access manager (e.g., 104) to form a global controller (e.g., 214) further includes: arranging first ones of the beta components to comprise a flip-flop (e.g., 272); and arranging second ones of the beta components to comprise a first delay line (e.g., 276B). Also regarding block 512, in some embodiments, the forming (e.g., 604) intercouplings amongst the components further results in at least: the flip-flop (e.g., 272) configured to receive a first bundle-selection signal (e.g., TRK_PRE); and the first delay line (e.g., 276B) being coupled to the flip-flop (e.g., 272) and being configured to generate a second bundle-selection signal (e.g., BBL_SEL) based on an output signal (e.g., TRK_PRE_D) of the flip-flop (e.g., 272).

Regarding block 506, in some embodiments, the using beta ones of the third components that comprise the global access manager (e.g., 104) to form a global controller (e.g., 214) further includes arranging third ones of the beta components to comprise a second delay line (e.g., 288). Also regarding block 512, in some embodiments, the forming (e.g., 604) intercouplings amongst the components further results in at least the second delay line (e.g., 288) being coupled between a lead latch (e.g., 272) and a follow latch (e.g., 274).

Regarding block 506, in some embodiments, the using beta ones of the third components that comprise the global access manager (e.g., 104) to form a global controller (e.g., 214) further includes: arranging third ones of the beta components to comprise a first inverter (e.g., 1st INV of 276B); and arranging fourth ones of the beta components to comprise a second inverter (e.g., 2nd INV of 276B). Also regarding block 512, in some embodiments, the forming (e.g., 604) intercouplings amongst the components further results in at least a tracking line (e.g., 280B) coupled in series between the first (e.g., 1st INV of 276B) and second (e.g., 2nd INV of 276B) inverters.

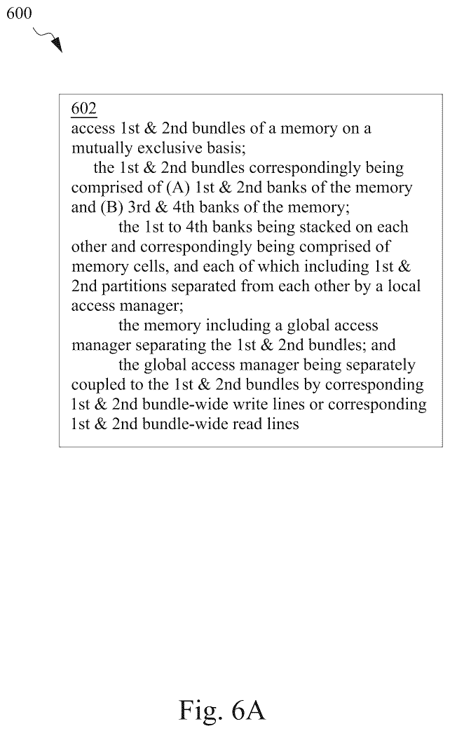

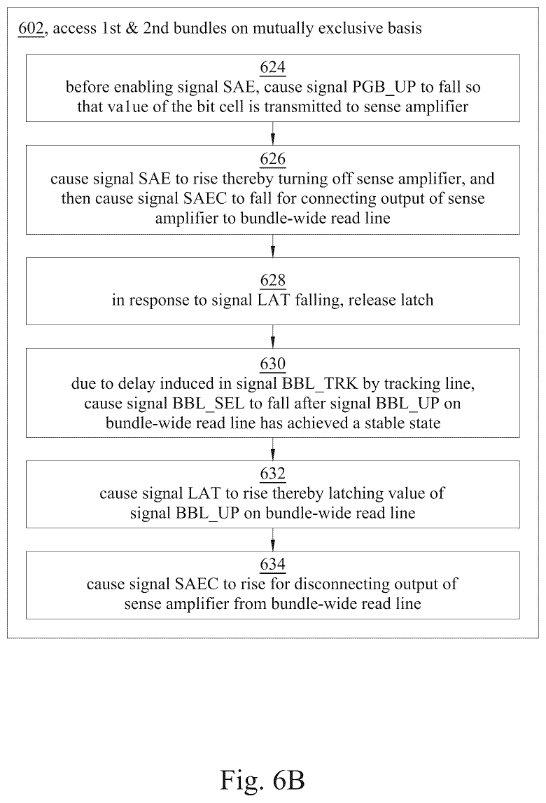

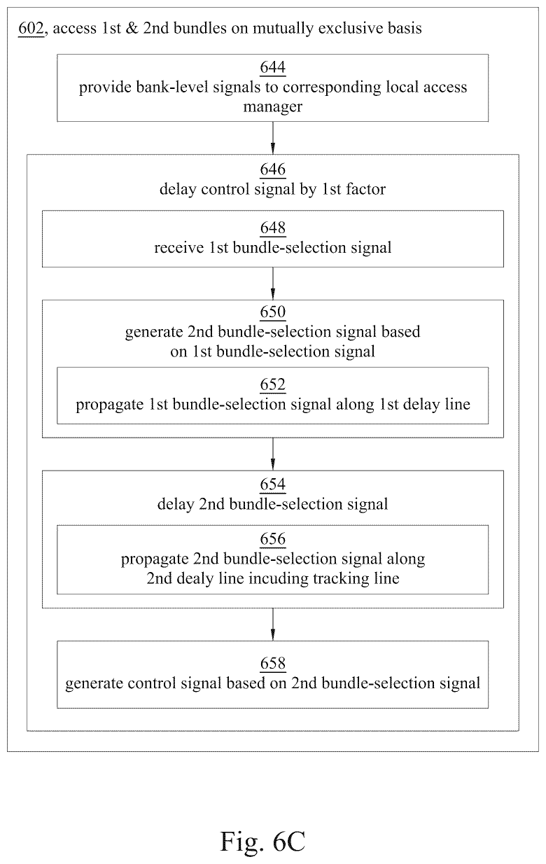

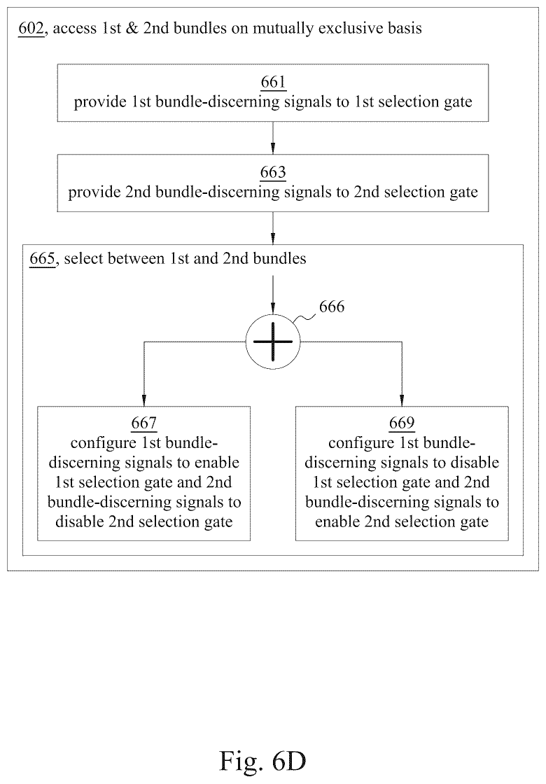

FIG. 6A is a flowchart (flow diagram) of a method 600 of operating a memory, in accordance with some embodiments.

Examples of a memory which is operable according to method 600 include the memories disclosed herein, or the like. Method 600 includes block 602.

At block 602, first and second bundles of memory are accessed on a mutually exclusive basis, wherein: the first & second bundles correspondingly are comprised of (A) first & second banks of the memory and (B) 3rd & 4th banks of the memory; the first to 4th banks are stacked on each other and correspondingly comprised of memory cells, and each of which includes first & second partitions separated from each other by a local access manager; the memory including a global access manager separating the first & second bundles; and the global access manager being separately coupled to the first & second bundles by corresponding first & second bundle-wide write lines or corresponding first & second bundle-wide read lines

Regarding block 602, examples of the first and second bundles correspondingly include bundles 102(1) and 102(2) of FIG. 1, bundles 202(1) and 202(2) of FIGS. 2A-2B, or the like. An example of the second bundle is bundle 102(2) of FIG. 1 which includes banks 106(3) and 106(4), or the like. Examples of the first and second bundles being accessed on a mutually exclusive basis include the discussion above of GIO 218 in the context of FIG. 2A, the discussion above of GCNT 218 and GIO 218 in the context of FIG. 2B, or the like.

Also regarding block 602, examples of the first to fourth banks correspondingly include banks 106(1)-106(4) of FIG. 1 which are stacked on each other relative to the Y-axis, banks 206(1)-206(4) of FIGS. 2A-2B which are stacked on each other relative to the Y-axis, or the like. An example of the first bundle including two banks is bundle 102(1) of FIG. 1 which includes banks 106(1) and 106(2), or the like. An example of the second bundle including two banks is bundle 102(2) of FIG. 1 which includes banks 106(3) and 106(4), or the like. Examples of the first and second partitions include partitions 108 and 110 correspondingly of each of banks 106(1)-106(4) of FIG. 1, or the like.

Also regarding block 602, examples of the memory cells include bit cells 250 of FIGS. 2A-2B, or the like. Examples of the local access managers include instances of local access managers 112 of FIG. 1, or the like. An example of the global access manager is global access manager 104 of FIG. 1, or the like.

Also regarding block 602, an example of the global access manager is global access manager 104 of FIG. 1 which separates bundle 102(1) from bundle 102(2), or the like. Examples of the first & second bundle-wide write lines include bundle-wide write lines 260(1) & 260(3) of FIG. 2A, bundle-wide write lines 260(3) & 260(4) of FIG. 2A, or the like. Examples of the first & second bundle-wide read lines include bundle-wide read lines 286(1) & 286(2) of FIG. 2B, or the like.

Also regarding block 602, examples of the structures that comprise the noted components are discussed above in the context of block 502 of FIG. 5. Regarding block 514, examples of forming intercouplings are discussed above in the context of block 514 of FIG. 5.

Regarding FIG. 6A, in some embodiments, the accessing first (e.g., 102(1)) and second (e.g., 102(2)) bundles of the memory on a mutually exclusive basis further includes: receiving first bundle-discerning signals (e.g., UD_SELB+BW_PRE) at a first selection gate (e.g., 256(1)), the first selection gate (e.g., 256(1)) being included in the global access manager (e.g., 104); providing a first driver (e.g., 258(1)) with an output signal of the first selection gate (e.g., 256(1)), the first driver (e.g., 258(1)) being coupled between the first selection gate (e.g., 256(1)) and the first bundle-wide write line (e.g., 260(1));
receiving second bundle-discerning signals (e.g., UD_SEL+BW_PRE) at second selection gate (e.g., 256(3)), the second selection gate (e.g., 256(3)) being included in the global access manager (e.g., 104); providing a second driver (e.g., 258(3)) with an output signal of the second selection gate (e.g., 256(3)), the second driver (e.g., 258(3)) being coupled between the second selection gate (e.g., 256(3)) and the second bundle-wide write line (e.g., 260(3)).

Regarding FIG. 6A, in some embodiments: the first bundle-discerning signals (e.g., UD_SELB +BW_PRE) include a first choice signal (e.g., UD_SELB) and a second choice signal (e.g., BW_PRE); the second bundle-discerning signals (e.g., UD_SEL+BW_PRE) include the second choice signal (e.g., BW_PRE) and a third choice signal (e.g., UD_SEL); the first selection gate (e.g., 256(1)) is a first AND gate; the second selection gate (e.g., 256(3)) is a second AND gate. In some embodiments, the accessing first (e.g., 102(1)) and second (e.g., 102(2)) bundles of the memory on a mutually exclusive basis further includes: providing each of the first (e.g., 256(1)) and second (e.g., 256(3)) AND gates with the second choice signal (e.g., BW_PRE); providing the first AND gate (e.g., 256(1)) the first choice signal (e.g., UD_SELB); and providing the second AND gate (e.g., 256(3)) with the third choice signal (e.g., UD_SEL).

Regarding FIG. 6A, in some embodiments, the accessing first (e.g., 102(1)) and second (e.g., 102(2)) bundles of the memory on a mutually exclusive basis further includes: receiving a first bundle-selection signal (e.g., TRK_PRE) at a flip-flop (e.g., 272), the flip-flop (e.g., 272) being included in a global controller (e.g., 214) that is included in the global access manager (e.g., 104); and using a first delay line (e.g., 276B) to generate a second bundle-selection signal (e.g., BBL_SEL) based on an output signal (e.g., TRK_PRE_D) of the flip-flop (e.g., 272), the first delay line (e.g., 276B) being included in the global controller (e.g., 214) and coupled to the flip-flop (e.g., 272).

Regarding FIG. 6A, in some embodiments, the accessing first (e.g., 102(1)) and second (e.g., 102(2)) bundles of the memory on a mutually exclusive basis further includes: receiving the second bundle-selection signal (e.g., BBL_SEL) at a second delay line (e.g., 288) from a lead latch (e.g., 272), the second delay line (e.g., 288) and the lead latch (e.g., 272) being included in the flip-flop (e.g., 272); using the second delay line (e.g., 288) to delay the second bundle-selection signal (e.g., BBL_SEL); and receiving the second bundle-selection signal (e.g., BBL_SEL) at a follow latch (e.g., 274) from the second delay line (e.g., 288), the follow latch (e.g., 274) also being included in the flip-flop (e.g., 272), and an output signal of the follow latch (e.g., 274) representing the output signal (e.g., TRK_PRE_D) of the flip-flop (e.g., 272).

Regarding FIG. 6A, in some embodiments, the using a first delay line (e.g., 276B) to generate a second bundle-selection signal (e.g., BBL_SEL) includes using the first delay line (e.g., 288) to delay the output signal (e.g., TRK_PRE_D) of the flip-flop (e.g., 272) resulting in a delayed version thereof, the delayed version of the output signal (e.g., TRK_PRE_D) of the flip-flop (e.g., 272) being the second bundle-selection signal (e.g., BBL_SEL). In some embodiments, the using the first delay line (e.g., 288) to delay the output signal (e.g., TRK_PRE_D) of the flip-flop (e.g., 272) includes propagating the output signal (e.g., TRK_PRE_D) of the flip-flop (e.g., 272) through a tracking line (e.g., 280B), and wherein: the tracking line (e.g., 280B) having a first length sufficient that a propagation delay therethrough shapes the second bundle-selection signal (e.g., BBL_SEL) to be slower than either a first bit signal (e.g., BBL_UP) or a second bit signal (e.g., BBL_DN) correspondingly on the first bundle-wide read line (e.g., 286(1)) or the second bundle-wide read line (e.g., 286(2)); and the first (e.g., 286(1)) and second (e.g., 286(2)) bundle-wide read lines having second (e.g., L_286(1)) and third (e.g., L_286(2)) lengths that exhibit correspondingly proportional second and third propagation delays therethrough.

FIG. 6B is a flowchart (flow diagram) of a method of writing to a memory, in accordance with some embodiments.

FIG. 6B provides details of an example of block 602 of FIG. 6A. Examples of a memory which is operable according to the method of FIG. 6B include the memories disclosed herein, e.g., memory 200B of FIG. 2B, or the like. An example of a timing diagram corresponding to FIG. 6B is the timing diagram (and waveforms included therein) of FIG. 3B, or the like. Accordingly, the discussion of FIG. 6B will be couched in the context contexts of FIGS. 2B and 3B. In FIG. 6B, block 602 includes block 624-634.

At block 624, before control signal SAE enables the sense amplifier (e.g., SA in FIG. 2B) to sense, pass gate control signal PGB_UP is caused to fall which couples the data stored in the corresponding instance of bit cell 250 correspondingly to inputs of sense amplifier SA. From block 624, flow proceeds to block 626.

At block 626, control signal SAE is caused to rise to enable the sense amplifier (e.g., SA in FIG. 2B) to sense. Then bank data signal DL_IN is caused to fall in the context of the example of FIG. 3B. From block 628, flow proceeds to block 628.

At block 628, in response to latch signal LAT falling, the value in latch 278 is released. In some embodiments, releasing the value in latch 278 is described as clearing the value in latch 278. In some embodiments, releasing the value in latch 278 is described as resetting the value in latch 278. Then control signal SAEC falls which causes SPUD circuit 284 to connect/couple the output of sense amplifier SA to bundle-wide read line 286(1), which causes bundle bit line signal BBL_UP to rise in the context of the example of FIG. 3B. The rise in bit line signal BBL_UP causes feedback signal BBL_FB_UP to fall. Also, shortly after control signal SAEC falls, trigger signal TRGR rises, which causes tracking signal BBL_TRK to rise. From block 628, flow proceeds to block 630.

At block 630, control signal BBL_SEL is caused to fall after bit line signal BBL_UP has achieved a stable state, which causes MUX 282 to select bundle bit line signal BBL_UP on bundle-wide read line 286(1). In the context of the example of FIG. 3B: when control signal BBL_SEL is in the logical high state, multiplexer 282 is configured to select bundle bit line signal BBL_DN; and when control signal BBL_SEL is in the logical low state, MUX 282 is configured to select bundle bit line signal BBL_UP. It is to be recalled that multiplex 282 is enable for making a selection between bundle bit line signal BBL_UP and bundle bit line signal BBL_DN when MUX enable signal MUX_EN (not shown) is in the second state and is disabled from making a selection between bundle bit line signal BBL_UP and bundle bit line signal BBL_DN when MUX enable signal MUX_EN (not shown) is in the first state; FIG. 3A assumes that MUX enable signal MUX_EN (not shown) is in the second state.

Regarding block 630, it is to be recalled that control signal BBL_SEL is a delayed and inverted version of tracking signal BBL_TRK. It is also to be recalled that tracking signal BBL_TRK propagates along tracking line 280B, where the length of the later is selected so that the delay tracking signal BBL_TRK causes control signal BBL_SEL to change state after either (A) bundle bit line signal BBL_UP on bundle-wide read line 286(1) has achieved a stable state in the context of bundle 202(1) being accessed or (B) bundle bit line signal BBL_DN on bundle-wide read line 286(2) has achieved a stable state in the context of bundle 202(1) being accessed, resulting in valid operation.

Regarding block 630, without the delay experienced by tracking signal BBL_TRK as the same propagates along tracking line 280B, tracking signal BBL_TRK otherwise would be at risk reaching the second inverter of delay line 276B too soon thereby causing control signal BBL_SEL to fall too soon. That is, tracking signal BBL_TRK otherwise reaching the second inverter of delay line 276B too soon thereby would cause control signal BBL_SEL to fall before either (A) bundle bit line signal BBL_UP on bundle-wide read line 286(1) has achieved a stable state in the context of bundle 202(1) being accessed or (B) bundle bit line signal BBL_DN on bundle-wide read line 286(2) has achieved a stable state in the context of bundle 202(1) being accessed, resulting in a glitch, i.e., an invalid operation. From block 630, flow proceeds to block 632

At block 632, after feedback signal BBL_FB is caused to fall, latch signal LAT is caused to rise which causes each of latches 278(3) and 278(4) to latch/store the voltage/value correspondingly of bit line signal BBL_UP on bundle-wide read line 286(1) of bundle 202(1) and bit line signal BBL_DN on bundle-wide read line 286(2) of bundle 202(2). From block 632, flow proceeds to block 634.

At block 634, control signal SAEC rises which causes SPUD circuit 284 to disconnect/decouple the output of sense amplifier SA from bundle-wide read line 286(1).

FIG. 6C is a flowchart (flow diagram) of a method of reading from a memory, in accordance with some embodiments.

FIG. 6C provides details of an example of block 602 of FIG. 6A. Examples of a memory which is operable according to the method of FIG. 6B include the memories disclosed herein, e.g., memory 200B of FIG. 2B, or the like. An example of a timing diagram corresponding to FIG. 6C is the timing diagram (and waveforms included therein) of FIG. 3B, or the like. Accordingly, the discussion of FIG. 6C will be couched in the context contexts of FIGS. 2B and 3B. FIG. 6C assumes a context of a selected one of memory cells (e.g., 250) in a corresponding one of first (e.g., 102(1)) and second (e.g., 102(2)) bundles. In FIG. 6B, block 602 includes block 644-658.

At block 644, bank-level signals (e.g., PGB_UP, SAE, DL_IN, SAEC, or the like) are provided to the corresponding local access manager (e.g., 112(x)) thereby causing data to be transferred from the selected one of the memory cells (e.g., 250) onto the corresponding one of the first (e.g., 286(1)) and second (e.g., 286(2)) bundle-wide read lines. From block 644, flow proceeds to block 646.

At block 646, a control signal (e.g., BBL_SEL) is delayed by a first delay factor, the control signal being configured to cause a multiplexer (e.g., 282) to select the first (e.g., 286(1)) or second (e.g., 286(2)) bundle-wide read line. The first delay factor is sufficient to induce a delay in the control signal (e.g., BBL_SEL) so that the voltage/value correspondingly of the signal (e.g., BBL_UP or BBL_DN) on the selected one of the first (e.g., 286(1)) and second (e.g., 286(2)) bundle-wide read lines reaches a stable state before the control signal (BBL_SEL) causes the multiplexer (282) to couple to select the first or second bundle-wide read line. Block 646 includes blocks 648-658. Within block 646, flow proceeds to block 648.

At block 648, a first bundle-selection signal (e.g., TRK_PRE) is received at first node (e.g., latch 273), the first node being included in the global access manager (e.g., 104). From block 648, flow proceeds to block 650.

At block 650, a second bundle-selection signal (e.g., BBL_TRK) is generated based on the first bundle-selection signal (e.g., TRK_PRE). Block 650 includes block 652.

At block 652, the first bundle-selection signal (e.g., TRK_PRE) is propagated along a first delay line (e.g., 288) resulting in a delayed version (e.g., TRK_PRE) of the same (e.g., TRK_PRE). The first delay line (e.g., 288) comprises at least a part of a signal path between the first node (e.g., latch 273) and a second node (e.g., latch 274), the fourth node being included in the global access manager (e.g., 104). Flow proceeds from block 652 and proceeds to exit block 650. From block 650, flow proceeds to block 654.

At block 654, propagation of the second bundle-selection signal (e.g., BBL_TRK) is delayed from a third node (e.g., output of first inverter of delay line 276) to a fourth node (e.g., input of first inverter of delay line 276) of a second delay line (e.g., 276) by a second delay factor. The second delay factor is based in part upon a length of the tracking line (e.g., 280B). Block 654 includes block 656.

At block 656, the second bundle-selection signal (BBL_TRK) is propagated along a tracking line (e.g., 280B) which comprises at least a part of a first signal path between the third node (e.g., output of first inverter of delay line 276) and the second node (e.g., input of the second inverter of delay line 276) of the second delay line (276). From block 656, flow exits block 654. From block 654, flow proceeds to block 658.

At block 658, the control signal (e.g., BBL_SEL) is generated based on the second bundle-selection signal (e.g., BBL_TRK).

FIG. 6D is a flowchart (flow diagram) of a method of writing to a memory, in accordance with some embodiments.

FIG. 6D provides details of an example of block 602 of FIG. 6A. Examples of a memory which is operable according to the method of FIG. 6B include the memories disclosed herein, e.g., memory 200A of FIG. 2A, or the like. An example of a timing diagram corresponding to FIG. 6D is the timing diagram (and waveforms included therein) of FIG. 3B, or the like. Accordingly, the discussion of FIG. 6B will be couched in the context contexts of FIGS. 2B and 3B. FIG. 6C assumes a context of a selected one of memory cells (e.g., 250) in a corresponding one of first (e.g., 102(1)) and second (e.g., 102(2)) bundles. In FIG. 6D, block 602 includes block 661-669.

At block 661, first bundle-discerning signals (e.g., UD_SELB and BW_PRE) are provided to a first selection gate (e.g., 256(1) in GIO 218. From block 661, flow proceeds to block 663.

At block 663, second bundle-discerning signals (e.g., UD_SEL and BW_PRE) are provided to a second selection gate (256(3)) in GIO 218. From block 663, flow proceeds to block 665.

At block 665, a selection is made between the first (102(1)) and second (102(2)) bundles. Block 665 includes blocks 667 and 669.

In block 665, flow can proceed to either block 667 or 669, as indicated by the exclusive-OR-flow symbol 666. At block 667, the first bundle-discerning signals (e.g., UD_SELB and BW_PRE) are configured to enable the first selection gate (e.g., 256(1) and thereby select the first (e.g., 102(1)) bundle and the second bundle-discerning signals (e.g., UD_SEL and BW_PRE) are configured to disable the second selection gate (e.g., 256(3)). At block 669, the first bundle-discerning signals (e.g., UD_SELB and BW_PRE) are configured to disable the first selection gate (e.g., 256(1) and the second bundle-discerning signals (e.g., UD_SEL and BW_PRE) are configured to enable the second selection gate (e.g., 256(3)) and thereby select the second bundle (e.g., 102(2)).

FIG. 7 is a flowchart (flow diagram) of a method 700 of manufacturing a system or device, in accordance with some embodiments.

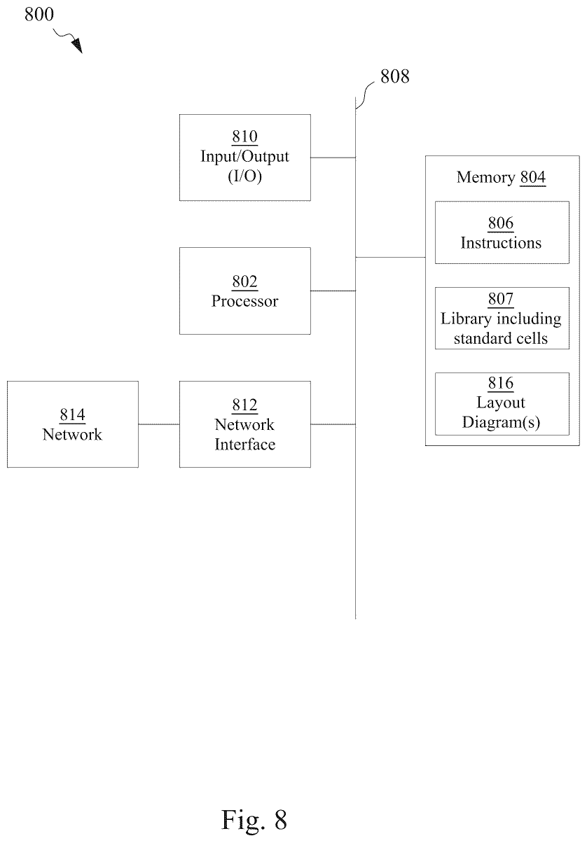

Method 700 is implementable, for example, using EDA system 800 (FIG. 8, discussed below) and an IC manufacturing system 900 (FIG. 9, discussed below), in accordance with some embodiments. Examples of memories which can be manufactured according to method 700 include the memories disclosed herein, or the like.

In FIG. 7, the method of flowchart 700 includes blocks 702-704. At block 702, a layout diagram is generated which, among other things, includes one or more layout diagrams corresponding to one or more of the memories disclosed herein, or the like. Block 702 is implementable, for example, using EDA system 800 (FIG. 8, discussed below), in accordance with some embodiments. From block 702, flow proceeds to block 704.

At block 704, based on the layout diagram, at least one of (A) one or more photolithographic exposures are made or (B) one or more photolithography masks are fabricated or (C) one or more components in a layer of a device, e.g., a device is fabricated. See discussion below of IC manufacturing system 900 in FIG. 9 below.

FIG. 8 is a block diagram of an electronic design automation (EDA) system 800 in accordance with some embodiments.

In some embodiments, EDA system 800 includes an automatic placement and routing (APR) system. In some embodiments, EDA system 800 is a general purpose computing device including a hardware processor 802 and a non-transitory, computer-readable storage medium 804. Storage medium 804, amongst other things, is encoded with, i.e., stores, computer program code 806, i.e., a set of executable instructions. Execution of instructions 806 by hardware processor 802 represents (at least in part) an EDA tool which implements a portion of or all, e.g., one or more methods of generating layout diagrams corresponding to the memories disclosed herein, or the like, in accordance with one or more embodiments (hereinafter, the noted processes and/or methods).

Storage medium 804, amongst other things, stores layout diagrams 811 such as layout diagrams corresponding to the memories disclosed herein, other the like.

Processor 802 is electrically coupled to computer-readable storage medium 804 via a bus 808. Processor 802 is further electrically coupled to an I/O interface 810 by a bus 808. A network interface 812 is further electrically connected to processor 802 via bus 808. Network interface 812 is connected to a network 814, so that processor 802 and computer-readable storage medium 804 are capable of connecting to external elements via network 814. Processor 802 is configured to execute computer program code 806 encoded in computer-readable storage medium 804 in order to cause EDA system 800 to be usable for performing a portion of or all the noted processes and/or methods. In one or more embodiments, processor 802 is a central processing unit (CPU), a multi-processor, a distributed processing system, an application specific integrated circuit (ASIC), and/or a suitable processing unit.

In one or more embodiments, computer-readable storage medium 804 is an electronic, magnetic, optical, electromagnetic, infrared, and/or a semiconductor system (or apparatus or device). For example, computer-readable storage medium 804 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 804 includes a compact disk-read only memory (CD-ROM), a compact disk-read/write (CD-R/W), and/or a digital video disc (DVD).

In one or more embodiments, storage medium 804 stores computer program code 806 configured to cause EDA system 800 (where such execution represents (at least in part) the EDA tool) to be usable for performing a portion of or all the noted processes and/or methods. In one or more embodiments, storage medium 804 further stores information which facilitates performing a portion of or all the noted processes and/or methods. In one or more embodiments, storage medium 804 stores library 807 of standard cells including standard cells that correspond to components of the memories disclosed herein. Storage medium 804 stores one or more layout diagrams 816 such as one or more layout diagrams corresponding to the memories disclosed herein, or the like.

EDA system 800 includes I/O interface 810. I/O interface 810 is coupled to external circuitry. In one or more embodiments, I/O interface 810 includes a keyboard, keypad, mouse, trackball, trackpad, touchscreen, and/or cursor direction keys for communicating information and commands to processor 802.

EDA system 800 further includes network interface 812 coupled to processor 802. Network interface 812 allows EDA system 800 to communicate with network 814, to which one or more other computer systems are connected. Network interface 812 includes wireless network interfaces such as BLUETOOTH, WIFI, WIMAX, GPRS, or WCDMA; or wired network interfaces such as ETHERNET, USB, or IEEE-1364. In one or more embodiments, a portion of or all noted processes and/or methods, is implemented in two or more EDA systems 800.

EDA system 800 is configured to receive information through I/O interface 810. The information received through I/O interface 810 includes one or more of instructions, data, design rules, libraries of standard cells, and/or other parameters for processing by processor 802. The information is transferred to processor 802 via bus 808. EDA system 800 is configured to receive information related to a user interface (UI) through I/O interface 810. The information is stored in computer-readable medium 804 as UI 842.

In some embodiments, a portion of or all the noted processes and/or methods is implemented as a standalone software application for execution by a processor. In some embodiments, a portion of or all the noted processes and/or methods is implemented as a software application that is a part of an additional software application. In some embodiments, a portion of or all the noted processes and/or methods is implemented as a plug-in to a software application. In some embodiments, at least one of the noted processes and/or methods is implemented as a software application that is a portion of an EDA tool. In some embodiments, a portion of or all the noted processes and/or methods is implemented as a software application that is used by EDA system 800. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 9 is a block diagram of an integrated circuit (IC) manufacturing system 900, and an IC manufacturing flow associated therewith, in accordance with some embodiments.

In some embodiments, based on the layout diagram generated by block 702 of FIG. 7, the IC manufacturing system 900 implements block 704 of FIG. 7 wherein at least one of (A) one or more semiconductor masks or (B) at least one component in a layer of an inchoate semiconductor integrated circuit is fabricated using manufacturing system 900. In some embodiments, the IC manufacturing system 900 implements the flowcharts of FIG. 5, or the like.

In FIG. 9, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in system 900 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and supplies services to and/or receives services from one or more of the other entities. In some embodiments, two or more of design house 920, mask house 930, and IC fab 950 is owned by a single larger company. In some embodiments, two or more of design house 920, mask house 930, and IC fab 950 coexist in a common facility and use common resources.

Design house (or design team) 920 generates an IC design layout 922. IC design layout 922 includes various geometrical patterns designed for an IC device 960. The geometrical patterns correspond to patterns of metal, oxide, or semiconductor layers that make up the various components of IC device 960 to be fabricated. The various layers combine to form various IC features. For example, a portion of IC design layout 922 includes various IC features, such as an active region, gate terminal, source and drain, metal lines or vias of an interlayer interconnection, and openings for bonding pads, to be formed in a semiconductor substrate (such as a silicon wafer) and various material layers disposed on the semiconductor substrate. Source/drain region(s) may refer to a source or a drain, individually or collectively, dependent upon the context. Design house 920 implements a proper design procedure to form IC design layout 922. The design procedure includes one or more of logic design, physical design or place and route. IC design layout 922 is presented in one or more data files having information of the geometrical patterns. For example, IC design layout 922 is expressed in a GDSII file format or DFII file format.

Mask house 930 includes data preparation 932 and mask fabrication 934. Mask house 930 uses IC design layout 922 to manufacture one or more masks 935 to be used for fabricating the various layers of IC device 960 according to IC design layout 922. Mask house 930 performs mask data preparation 932, where IC design layout 922 is translated into a representative data file (“RDF”). Mask data preparation 932 supplies the RDF to mask fabrication 934. Mask fabrication 934 includes a mask writer. A mask writer converts the RDF to an image on a substrate, such as a mask (reticle) or a semiconductor wafer. The design layout is manipulated by mask data preparation 932 to comply with particular characteristics of the mask writer and/or requirements of IC fab 950. In FIG. 9, mask data preparation 932, mask fabrication 934, and mask 935 are illustrated as separate elements. In some embodiments, mask data preparation 932 and mask fabrication 934 are collectively referred to as mask data preparation.

In some embodiments, mask data preparation 932 includes optical proximity correction (OPC) which uses lithography enhancement techniques to compensate for image errors, such as those that can arise from diffraction, interference, other process effects and the like. OPC adjusts IC design layout 922. In some embodiments, mask data preparation 932 includes further resolution enhancement techniques (RET), such as off-axis illumination, sub-resolution adjust features, phase-shifting masks, other suitable techniques, and the like or combinations thereof. In some embodiments, inverse lithography technology (ILT) is further used, which treats OPC as an inverse imaging problem.

In some embodiments, mask data preparation 932 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 934, which may undo part of the modifications performed by OPC in order to meet mask creation rules.

In some embodiments, mask data preparation 932 includes lithography process checking (LPC) that simulates processing that will be implemented by IC fab 950 to fabricate IC device 960. LPC simulates this processing based on IC design layout 922 to fabricate a simulated manufactured device, such as IC device 960. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been fabricated by LPC, if the simulated device is not close enough in shape to satisfy design rules, OPC and/or MRC are repeated to further refine IC design layout 922.

The above description of mask data preparation 932 has been simplified for the purposes of clarity. In some embodiments, mask data preparation 932 includes additional features such as a logic operation (LOP) to modify the IC design layout according to manufacturing rules. Additionally, the processes applied to IC design layout 922 during data preparation 932 may be executed in a variety of different orders.

After mask data preparation 932 and during mask fabrication 934, a mask 935 or a group of masks 935 are fabricated based on the modified IC design layout. In some embodiments, an electron-beam (e-beam) or a mechanism of multiple e-beams is used to form a pattern on a mask (photomask or reticle) based on the modified IC design layout. The masks are formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask is an attenuated PSM or alternating PSM. The mask(s) generated by mask fabrication 934 is used in a variety of processes. For example, such a mask(s) is used in an ion implantation process to form various doped regions in the semiconductor wafer, in an etching process to form various etching regions in the semiconductor wafer, and/or in other suitable processes.

IC fab 950 is an IC fabrication business that includes one or more manufacturing facilities for the fabrication of a variety of different IC products. In some embodiments, IC fab 950 is a semiconductor foundry. For example, there may be a manufacturing facility for the front end fabrication of a plurality of IC products (front-end-of-line (FEOL) fabrication), while a second manufacturing facility may supply the back end fabrication for the interconnection and packaging of the IC products (back-end-of-line (BEOL) fabrication), and a third manufacturing facility may supply other services for the foundry business.

IC fab 950 uses mask (or masks) 935 fabricated by mask house 930 to fabricate IC device 960 using fabrication tools 952. Thus, IC fab 950 at least indirectly uses IC design layout 922 to fabricate IC device 960. In some embodiments, a semiconductor wafer 953 is fabricated by IC fab 950 using mask (or masks) 935 to form IC device 960. Semiconductor wafer 953 includes a silicon substrate or other proper substrate having material layers formed thereon. Semiconductor wafer further includes one or more of various doped regions, dielectric features, multilevel interconnects, and the like (formed at subsequent manufacturing steps).

In some embodiments, a memory includes first, second, third and fourth banks stacked on each other relative to a first direction and correspondingly including memory cells, and each of which including: first and second partitions and a local access manager; (A) the first and second banks and (B) the third and fourth banks being organized as corresponding first and second bundles; and a global access manager separating the first and second bundles relative to the first direction, the global access manager being separately coupled to the first and second bundles by corresponding first and second bundle-wide write lines or corresponding first and second bundle-wide read lines.

In some embodiments, the global access manager is configured to selectively access the first and second bundles on a mutually exclusive basis.

In some embodiments, the global access manager includes: first and second global I/O circuits and a global controller.

In some embodiments, each of the first and second global I/O circuits includes: a first selection gate configured to receive first bundle-discerning signals; a second selection gate configured to receive second bundle-discerning signals; a first driver coupled between the first selection gate and the first bundle-wide write line; and a second driver coupled between the second selection gate and the second bundle-wide write line.

In some embodiments, the first bundle-discerning signals include a first choice signal and a second choice signal; the second bundle-discerning signals include the second choice signal and a third choice signal; the first selection gate is a first AND gate; the second selection gate is a second AND gate; and each of the first and second AND gates is configured to receive the second choice signal; the first AND gate is further configured to receive the first choice signal; and the second AND gate is further configured to receive the third choice signal.

In some embodiments, the global controller includes a flip-flop coupled to a first delay line; the flip-flop is configured to receive a first bundle-selection signal; and the first delay line is configured to generate a second bundle-selection signal based on an output signal of the flip-flop.

In some embodiments, the first delay line includes a tracking line coupled in series between first and second inverters.

In some embodiments, the first and second bundle-wide read lines exhibit corresponding first and second propagation delays proportional to first and second lengths correspondingly of the first and second bundle-wide read lines; the second bundle-selection signal is based on the output signal of the flip-flop; the tracking line exhibits a third propagation delay proportional to a third length of the tracking line; and the third length of the tracking line delays the second bundle-selection signal to be slower than either first or second bit signals correspondingly on the first or second bundle-wide read lines.

In some embodiments, each of the first and second global I/O circuits includes: first and second latches coupled correspondingly to the first and second bundle-wide read lines; and a multiplexer coupled to each of the first and second latches, the multiplexer being configured to receive the second bundle-selection signal, and the multiplexer being further configured to select first or second bit signals correspondingly on the first or second bundle-wide read lines according to the second bundle-selection signal.

In some embodiments, a method (of manufacturing a memory) includes forming structures that comprise components, the components including memory cells, local access managers and a global access manager, the forming structures that comprise components including: arranging first ones of the components that comprise the memory cells into first, second, third and fourth banks that are stacked on each other relative to a first direction including, for each of the first to fourth banks, arranging alpha ones and beta ones of the first components into corresponding first and second partitions; arranging (A) the first and second banks and (B) the third and fourth banks as corresponding first and second bundles; and arranging second ones of the components that comprise the local access managers so that, for each of the first, second, third and fourth banks, the first and second partitions are separated from each other by a corresponding one of the local access managers relative to the first direction; arranging third ones of the components that comprise the global access manager so that the global access manager separates the first and second bundles relative to the first direction; and forming intercouplings amongst the components resulting in at least first and second bundle-wide write lines or first and second bundle-wide read lines that separately couple the global access manager correspondingly to the first and second bundles.

In some embodiments, the arranging third ones of the components that comprise the global access manager includes: configuring the global access manager to access the first and second bundles on a mutually exclusive basis.

In some embodiments, the forming structures that comprise components further includes: using alpha ones of the third components that comprise the global access manager to form first and second global I/O circuits; using beta ones of the third components that comprise the global access manager to form a global controller; and arranging the beta ones of the third components that comprise the global access manager so that the global controller separates the first and second global I/O circuits relative to a second direction perpendicular to the first direction.

In some embodiments, the using beta ones of the third components that comprise the global access manager to form a global controller further includes arranging fifth ones of the beta components to comprise a third selection gate, arranging sixth ones of the beta components to comprise a fourth selection gate, arranging seventh ones of the beta components to comprise a third driver, and arranging eighth ones of the beta components to comprise a fourth driver; and the forming intercouplings amongst the components further results in at least third and fourth bundle-wide write lines that separately couple the global access manager correspondingly to the first and second bundles, the third selection gate being operable to receive third selection signals, the fourth selection gate being operable to receive fourth selection signals, the third driver being coupled between the third selection gate and the third bundle-wide write line, and the fourth driver being coupled between the third selection gate and the fourth bundle-wide write line.

In some embodiments, the using beta ones of the third components that comprise the global access manager to form a global controller includes: arranging first ones of the beta components to comprise a first selection gate; arranging second ones of the beta components to comprise a second selection gate; arranging third ones of the beta components to comprise a first driver; and arranging fourth ones of the beta components to comprise a second driver. In some embodiments, the forming intercouplings amongst the components further results in at least: the first selection gate configured to receive first bundle-selection signals; the second selection gate being configured to receive second bundle-selection signals; the first driver being coupled between the first selection gate and the first bundle-wide write line; and the second driver being coupled between the second selection gate and the second bundle-wide write line.

In some embodiments, the using beta ones of the third components that comprise the global access manager to form a global controller includes: arranging first ones of the beta components to comprise a flip-flop; and arranging second ones of the beta components to comprise a first delay line. In some embodiments, the forming intercouplings amongst the components further results in at least: the flip-flop configured to receive a first bundle-selection signal; and the first delay line being coupled to the flip-flop and being configured to generate a second bundle-selection signal based on an output signal of the flip-flop.

In some embodiments, a method (of reading from memory) includes: accessing first and second bundles of the memory on a mutually exclusive basis; the first and second bundles correspondingly being comprised of (A) first and second banks of the memory and (B) third and fourth banks of the memory; the first, second, third and fourth banks being stacked on each other relative to a first direction and correspondingly being comprised of memory cells, and each of which including first and second partitions and a local access manager; the memory including a global access manager separating the first and second bundles relative to the first direction; and the global access manager being separately coupled to the first and second bundles by corresponding first and second bundle-wide write lines, and the global access manager including a first delay line and a multiplexer coupled to the first and second bundles by corresponding first and second bundle-wide read lines; for a selected one of the memory cells in the corresponding one of first and second bundles, the accessing first and second bundles including providing bank-level signals to the corresponding local access manager thereby causing data to be transferred from the selected one of the memory cells onto the corresponding one of the first and second bundle-wide read lines, and delaying a control signal by a first delay factor; and the control signal being configured to cause the multiplexer to select the first or second bundle-wide read line.

In some embodiments, for the selected one of the memory cells in the corresponding one of first and second bundles, the delaying a control signal includes: delaying propagation of a first bundle-selection signal from a first node to a second node of the first delay line by a second delay factor, the first delay factor being based on the second delay factor; and generating the control signal based on the first bundle-selection signal.

In some embodiments, the delaying propagation of a first bundle-selection signal includes propagating the first bundle-selection signal along a tracking line which comprises at least a part of a first signal path between the first node and the second node of the first delay line; and the second delay factor being based in part upon a length of the tracking line.

In some embodiments, the delaying propagation of a first bundle-selection signal includes: receiving a second bundle-selection signal at a third node, the third node being included in the global access manager; and generating the first bundle-selection signal based on the second bundle-selection signal.

In some embodiments, the generating the first bundle-selection signal includes propagating the second bundle-selection signal along a second delay line which comprises at least a part of a signal path between the third node and a fourth node, the fourth node being included in the global access manager.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

1. A memory comprising:
first, second, third and fourth banks stacked on each other relative to a first direction and correspondingly including memory cells, and each of which including:
first and second partitions and a local access manager;
(A) the first and second banks and (B) the third and fourth banks being organized as corresponding first and second bundles; and
a global access manager separating the first and second bundles relative to the first direction,
the global access manager being separately coupled to the first and second bundles by corresponding first and second bundle-wide write lines or corresponding first and second bundle-wide read lines.

2. The memory of claim 1, wherein:
the global access manager is configured to selectively access the first and second bundles on a mutually exclusive basis.

3. The memory of claim 1, wherein the global access manager includes:
first and second global I/O circuits separated and a global controller.

4. The memory of claim 3, wherein each of the first and second global I/O circuits includes:
a first selection gate configured to receive first bundle-discerning signals;
a second selection gate configured to receive second bundle-discerning signals;
a first driver coupled between the first selection gate and the first bundle-wide write line; and
a second driver coupled between the second selection gate and the second bundle-wide write line.

5. The memory of claim 4, wherein:
the first bundle-discerning signals include a first choice signal and a second choice signal;
the second bundle-discerning signals include the second choice signal and a third choice signal;
the first selection gate is a first AND gate;
the second selection gate is a second AND gate; and
each of the first and second AND gates is configured to receive the second choice signal;
the first AND gate is further configured to receive the first choice signal; and
the second AND gate is further configured to receive the third choice signal.

6. The memory of claim 3, wherein:
the global controller includes a flip-flop coupled to a first delay line;
the flip-flop is configured to receive a first bundle-selection signal; and
the first delay line is configured to generate a second bundle-selection signal based on an output signal of the flip-flop.

7. The memory of claim 6, wherein:
the first delay line includes a tracking line coupled in series between first and second inverters.

8. The memory of claim 7, wherein:
the first and second bundle-wide read lines exhibit corresponding first and second propagation delays proportional to first and second lengths correspondingly of the first and second bundle-wide read lines;
the second bundle-selection signal is based on the output signal of the flip-flop;
the tracking line exhibits a third propagation delay proportional to a third length of the tracking line; and
the third length of the tracking line delays the second bundle-selection signal to be slower than either first or second bit signals correspondingly on the first or second bundle-wide read lines.

9. The memory of claim 6, wherein each of the first and second global I/O circuits includes:
first and second latches coupled correspondingly to the first and second bundle-wide read lines; and
a multiplexer coupled to each of the first and second latches,
the multiplexer being configured to receive the second bundle-selection signal, and
the multiplexer being further configured to select first or second bit signals correspondingly on the first or second bundle-wide read lines according to the second bundle-selection signal.

10. A method of manufacturing a memory, the method comprising:
forming structures that comprise components, the components including memory cells, local access managers and a global access manager, the forming structures that comprise components including:
arranging first ones of the components that comprise the memory cells into first, second, third and fourth banks that are stacked on each other relative to a first direction including, for each of the first to fourth banks, arranging alpha ones and beta ones of the first components into corresponding first and second partitions;
arranging (A) the first and second banks and (B) the third and fourth banks as corresponding first and second bundles; and
arranging second ones of the components that comprise the local access managers so that, for each of the first, second, third and fourth banks, the first and second partitions are separated from each other by a corresponding one of the local access managers relative to the first direction;
arranging third ones of the components that comprise the global access manager so that the global access manager separates the first and second bundles relative to the first direction; and
forming intercouplings amongst the components resulting in at least:
first and second bundle-wide write lines or first and second bundle-wide read lines that separately couple the global access manager correspondingly to the first and second bundles.

11. The method of claim 10, wherein the arranging third ones of the components that comprise the global access manager includes:
configuring the global access manager to access the first and second bundles on a mutually exclusive basis.

12. The method of claim 10, wherein the forming structures that comprise components further includes:
using alpha ones of the third components that comprise the global access manager to form first and second global I/O circuits;
using beta ones of the third components that comprise the global access manager to form a global controller; and
arranging the beta ones of the third components that comprise the global access manager so that the global controller separates the first and second global I/O circuits relative to a second direction perpendicular to the first direction.

13. The method of claim 12, wherein:
the using beta ones of the third components that comprise the global access manager to form a global controller includes:
arranging first ones of the beta components to comprise a first selection gate;
arranging second ones of the beta components to comprise a second selection gate;
arranging third ones of the beta components to comprise a first driver; and
arranging fourth ones of the beta components to comprise a second driver; and
the forming intercouplings amongst the components further results in at least:
the first selection gate configured to receive first bundle-selection signals;
the second selection gate being configured to receive second bundle-selection signals;
the first driver being coupled between the first selection gate and the first bundle-wide write line; and
the second driver being coupled between the second selection gate and the second bundle-wide write line.

14. The method of claim 13, wherein:
the using beta ones of the third components that comprise the global access manager to form a global controller further includes:
arranging fifth ones of the beta components to comprise a third selection gate;
arranging sixth ones of the beta components to comprise a fourth selection gate;
arranging seventh ones of the beta components to comprise a third driver; and
arranging eighth ones of the beta components to comprise a fourth driver; and
the forming intercouplings amongst the components further results in at least:
third and fourth bundle-wide write lines that separately couple the global access manager correspondingly to the first and second bundles;
the third selection gate being operable to receive third selection signals;
the fourth selection gate being operable to receive fourth selection signals;
the third driver being coupled between the third selection gate and the third bundle-wide write line; and
the fourth driver being coupled between the third selection gate and the fourth bundle-wide write line.

15. The method of claim 12, wherein:
the using beta ones of the third components that comprise the global access manager to form a global controller includes:
arranging first ones of the beta components to comprise a flip-flop; and
arranging second ones of the beta components to comprise a first delay line; and
the forming intercouplings amongst the components further results in at least:
the flip-flop configured to receive a first bundle-selection signal; and
the first delay line being coupled to the flip-flop and being configured to generate a second bundle-selection signal based on an output signal of the flip-flop.

16. A method of reading from a memory, the method comprising:
accessing first and second bundles of the memory on a mutually exclusive basis;
the first and second bundles correspondingly being comprised of (A) first and second banks of the memory and (B) third and fourth banks of the memory;
the first, second, third and fourth banks being stacked on each other relative to a first direction and correspondingly being comprised of memory cells, and each of which including first and second partitions and a local access manager, the memory including a global access manager separating the first and second bundles relative to the first direction, and the global access manager being separately coupled to the first and second bundles by corresponding first and second bundle-wide write lines, and the global access manager including a first delay line and a multiplexer coupled to the first and second bundles by corresponding first and second bundle-wide read lines;
for a selected one of the memory cells in the corresponding one of first and second bundles, the accessing first and second bundles including:
providing bank-level signals to the corresponding local access manager thereby causing data to be transferred from the selected one of the memory cells onto the corresponding one of the first and second bundle-wide read lines; and
delaying a control signal by a first delay factor; and
the control signal being configured to cause the multiplexer to select the first or second bundle-wide read line.

17. The method of claim 16, wherein, for the selected one of the memory cells in the corresponding one of first and second bundles, the delaying a control signal includes:
delaying propagation of a first bundle-selection signal from a first node to a second node of the first delay line by a second delay factor,
the first delay factor being based on the second delay factor; and
generating the control signal based on the first bundle-selection signal.

18. The method of claim 17, wherein:
the delaying propagation of a first bundle-selection signal includes:
propagating the first bundle-selection signal along a tracking line which comprises at least a part of a first signal path between the first node and the second node of the first delay line; and
the second delay factor being based in part upon a length of the tracking line.

19. The method of claim 17, wherein:
the delaying propagation of a first bundle-selection signal includes:
receiving a second bundle-selection signal at a third node,
the third node being included in the global access manager; and
generating the first bundle-selection signal based on the second bundle-selection signal.

20. The method of claim 19, wherein:
the generating the first bundle-selection signal includes:
propagating the second bundle-selection signal along a second delay line which comprises at least a part of a signal path between the third node and a fourth node, the fourth node being included in the global access manager.
